(19) United States
(12) Patent Application Publication
(10) Pub. No.: US 2025/0366349 A1
(43) Pub. Date: Nov. 27, 2025

(54) DISPLAY DEVICE

(71) Applicant: SAMSUNG DISPLAY CO., LTD., YONGIN-SI (KR)

(72) Inventors: Se Hee KIM, Yongin-si (KR); Seung Han KIM, Yongin-si (KR); Sang Min HONG, Yongin-si (KR)

(21) Appl. No.: 19/015,812

(22) Filed: Jan. 10, 2025

(30) Foreign Application Priority Data
May 21, 2024 (KR) 10-2024-0065963

(51) Int. Cl. H10K 59/80; H10K 59/122

(52) U.S. Cl. CPC H10K 59/873; H10K 59/122

(57) ABSTRACT

A display device includes a plurality of pixels comprising a plurality of emission areas spaced apart from each other. A first light blocking layer is disposed on the display area and includes a plurality of holes overlapping the plurality of emission areas. A plurality of color filters is disposed on the first light blocking layer and is arranged to respectively correspond to the plurality of holes. A second light blocking layer is disposed on the plurality of color filters and is arranged to correspond to the plurality of emission areas of a first portion of the plurality of pixels. The second light blocking layer is disposed to surround the plurality of emission areas of the first portion of the plurality of pixels in a plan view and comprises a plurality of light blocking patterns overlapping the plurality of emission areas of the first portion of the plurality of pixels.

### CROSS-REFERENCE TO RELATED APPLICATION

This application claims priority under 35 U.S.C. § 119 to Korean Patent Application No. 10-2024-0065963, filed on May 21, 2024 in the Korean Intellectual Property Office, the disclosure of which is incorporated by reference in its entirety herein.

### 1. TECHNICAL FIELD

Embodiments of the present disclosure relate to a display device.

### 2. DISCUSSION OF RELATED ART

Consumer demands for display devices for displaying images that are applied to various different electronic devices has increased along with the advancement of the information-orientated society. For example, display devices are applied to electronic devices, such as smartphones, digital cameras, laptop computers, navigation devices, and smart televisions.

The display device may be a flat panel display device, such as a liquid crystal display device, a field emission display device and an organic light emitting display device. Among the flat panel display devices, in the organic light emitting display device, since each of the pixels of a display panel includes a light emitting element capable of emitting light by itself, an image can be displayed without a backlight unit providing light to the display panel.

### SUMMARY

Aspects of embodiments of the present disclosure provide a display device including a plurality of light blocking layers disposed in different layers.

Aspects of embodiments of the present disclosure also provide a display device capable of providing a privacy protection mode by including a light blocking layer disposed in some pixels.

However, aspects of embodiments of the present disclosure are not restricted to those set forth herein. The above and other aspects of embodiments of the present disclosure will become more apparent to one of ordinary skill in the art to which the present disclosure pertains by referencing the detailed description of the present disclosure given below.

According to an e of the present disclosure, a display device includes a plurality of pixels comprising a plurality of emission areas spaced apart from each other. A first light blocking layer is disposed on the display area. The first light blocking layer comprising a plurality of holes overlapping the plurality of emission areas. A plurality of color filters is disposed on the first light blocking layer. The plurality of color filters is arranged to respectively correspond to the plurality of holes. A second light blocking layer is disposed on the plurality of color filters. The second light blocking layer is arranged to correspond to the plurality of emission areas of a first portion of the plurality of pixels. The second light blocking layer is disposed to surround the plurality of emission areas of the first portion of the plurality of pixels in a plan view. The second light blocking layer comprises a plurality of light blocking patterns overlapping the plurality of emission areas of the first portion of the plurality of pixels.

In an embodiment, the plurality of pixels comprise a first pixel, a second pixel, a third pixel, and a fourth pixel, and the first portion of the plurality of pixels includes the second pixel and the fourth pixel and does not include the first pixel and the third pixel.

In an embodiment, the second pixel and the fourth pixel are spaced apart in a first direction, the first pixel and the third pixel are spaced apart in a second direction crossing the first direction, and planar shapes of the plurality of light blocking patterns are symmetrical to each other with respect to an axis extending in the second direction between the second pixel and the fourth pixel.

In an embodiment, the plurality of emission areas of the first portion of the plurality of pixels comprises at least a first emission area, the plurality of light blocking patterns comprise at least a first light blocking pattern overlapping the first emission area, and a gap in the plan view between a side surface of the first emission area and an inner side surface of the first light blocking pattern is in a range of about 1% to about 10% of a diameter of the first emission area.

In an embodiment, the inner side surface of the first light blocking pattern overlaps the first emission area and does not overlap the first light blocking layer, and an outer side surface of the first light blocking pattern overlaps the first light blocking layer and does not overlap the first emission area.

In an embodiment, the plurality of emission areas of the first portion of the plurality of pixels comprises a second emission area and a third emission area, the plurality of light blocking patterns comprise a second light blocking pattern overlapping the second emission area and a third light blocking pattern overlapping the third emission area, a width of the second light blocking pattern is greater than a width of the first light blocking pattern and a width of the third light blocking pattern, and the width of the first light blocking pattern is greater than the width of the third light blocking pattern.

In an embodiment, a diameter of the third emission area is greater than the diameter of the first emission area and a diameter of the second emission area, and the diameter of the first emission area is greater than the diameter of the second emission area.

In an embodiment, the plurality of holes comprise at least a first hole overlapping the first emission area, and first side surfaces of the first emission area and the first hole adjacent to each other are aligned and coincide with each other in a thickness direction.

In an embodiment, a gap in the plan view between a second side surface of the first emission area opposite to the first side surface of the first emission area and a second side surface of the first hole opposite to the first side surface of the first hole is in a range of about 2% to about 20% of the diameter of the first emission area.

In an embodiment, each of the plurality of light blocking patterns has a same width as each other.

In an embodiment, the plurality of light blocking patterns have a semi-ring shape that is opened in one direction in the plan view, and an opening direction of the plurality of light blocking patterns disposed in the second pixel and an opening direction of the plurality of light blocking patterns disposed in the fourth pixel face each other.

In an embodiment, the plurality of light blocking patterns overlaps the plurality of holes overlapping the plurality of emission areas corresponding thereto, respectively.

In an embodiment, the display device further comprises a pixel electrode disposed on the display area, a pixel defining film covering an edge of the pixel electrode, a light emitting layer disposed on the pixel electrode, and a common electrode disposed on the light emitting layer. The emission area is defined by an opening of the pixel defining film overlapping the pixel electrode.

According to an embodiment of the present disclosure, a display device comprises a substrate. A light emitting element layer is disposed on the substrate. The light emitting element layer comprises a plurality of emission areas. An encapsulation layer is disposed on the light emitting element layer. A first light blocking layer is disposed on the encapsulation layer. The first light blocking layer comprises a plurality of holes respectively disposed to correspond to the plurality of emission areas. A color filter layer is disposed on the encapsulation layer. The color filter layer comprises a plurality of color filters disposed in the plurality of holes. A light blocking member layer is disposed on the color filter layer. The light blocking member layer comprising a second light blocking layer overlapping a first portion of the plurality of emission areas. The second light blocking layer overlapping the first portion of the plurality of emission areas overlaps the first light blocking layer and the plurality of holes.

In an embodiment, the plurality of emission areas includes a first pixel and a second pixel, the second light blocking layer comprises a plurality of light blocking patterns, and the plurality of light blocking patterns overlaps the second pixel and does not overlap the first pixel.

In an embodiment, the plurality of emission areas disposed to overlap the second pixel comprises at least a first emission area, the plurality of light blocking patterns comprises at least a first light blocking pattern overlapping the first emission area, and a gap in a plan view between a side surface of the first emission area and an inner side surface of the first light blocking pattern is in a range from about 1% to about 10% of a diameter of the first emission area.

In an embodiment, the plurality of holes comprise at least a first hole overlapping the first emission area, and first side surfaces of the first emission area and the first hole adjacent to each other are aligned and coincide with each other in a thickness direction.

In an embodiment, a gap in the plan view between a second side surface of the first emission area opposite to the first side surface of the first emission area and a second side surface of the first hole opposite to the first side surface of the first hole is in a range of about 2% to about 20% of a diameter of the first emission area.

In an embodiment, the plurality of emission areas includes a third pixel spaced apart from the second pixel in a first direction, the plurality of light blocking patterns overlap the third pixel, and the plurality of light blocking patterns have a semi-ring shape that is opened in one direction.

In an embodiment, an opening direction of the plurality of light blocking patterns disposed in the second pixel and an opening direction of the plurality of light blocking patterns disposed in the third pixel face each other.

The display device according to an embodiment includes a first light blocking layer and a second light blocking layer, thereby controlling the visibility of the screen at a specific viewing angle according to the emission mode of the display device. In the display device, the shape and layout of emission areas and light blocking patterns of the first light blocking layer and the second light blocking layer are designed, so that the visibility at a specific viewing angle may be blocked to provide a privacy mode to the user and the front luminance may be increased.

However, effects according to embodiments of the present disclosure are not limited to those described above and various other effects are incorporated herein.

### BRIEF DESCRIPTION OF THE DRAWINGS

The above and other aspects and features of embodiments of the present disclosure will become more apparent by describing in detail non-limiting embodiments thereof with reference to the attached drawings, in which:

FIG. 1 is a schematic perspective view of an electronic device according to an embodiment of the present disclosure;

FIG. 2 is a perspective view illustrating a display device included in an electronic device according to an embodiment of the present disclosure;

FIG. 3 is a cross-sectional view of the display device of FIG. 2 viewed from the side according to an embodiment of the present disclosure;

FIG. 4 is a plan view of the arrangement of pixel electrodes in the display area of the display device according to an embodiment of the present disclosure;

FIG. 5 is a plan view illustrating the arrangement of a pixel electrode, a first light blocking layer, and color filters in a display area of a display device according to an embodiment of the present disclosure;

FIG. 6 is a plan view of the arrangement of the emission areas and the second light blocking layer in the display area of the display device according to an embodiment of the present disclosure;

FIG. 7 is a schematic diagram illustrating light emitting pixels according to an emission mode of the display device according to an embodiment of the present disclosure;

FIG. 8 is a cross-sectional view taken along line X1-X1′ of FIGS. 5 and 6 according to an embodiment of the present disclosure;

FIG. 9 is a cross-sectional view taken along line X2-X2′ of FIG. 6 according to an embodiment of the present disclosure;

FIG. 10 is a cross-sectional view taken along line X3-X3′ of FIG. 6 according to an embodiment of the present disclosure;

FIG. 11 is a diagram illustrating the relative arrangement of an emission area and a second light blocking layer disposed in the second pixel of the display device according to an embodiment of the present disclosure;

FIG. 12 is a diagram illustrating the relative arrangement of an emission area and a second light blocking layer disposed in the fourth pixel of the display device according to an embodiment of the present disclosure;

FIG. 13 is an diagram illustrating an emission direction of light emitted from an emission area of a display device and a relative arrangement of a second light blocking layer according to an embodiment of the present disclosure;

FIG. 14 is a cross-sectional view showing a fourth pixel of a display device according to an embodiment of the present disclosure;

FIG. 15 is a diagram illustrating the relative arrangement of an emission area and a second light blocking layer disposed in the second pixel of the display device according to an embodiment of the present disclosure;

FIG. 16 is a diagram illustrating the relative arrangement of an emission area and a second light blocking layer disposed in the fourth pixel of the display device according to an embodiment of the present disclosure; and

FIG. 17 is an diagram illustrating an emission direction of light emitted from an emission area of a display device and a relative arrangement of a second light blocking layer according to an embodiment of the present disclosure.

### DETAILED DESCRIPTION OF EMBODIMENTS

The present disclosure will now be described more fully hereinafter with reference to the accompanying drawings, in which non-limiting embodiments of the present disclosure are described. The present disclosure may, however, be embodied in various different forms and should not be construed as limited to the described embodiments set forth herein.

It will also be understood that when a layer is referred to as being “on” another layer or substrate, it can be directly on the other layer or substrate, or intervening layers may also be present. When a layer is referred to as being “directly on” another layer or substrate, no intervening layers may be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the present invention. Similarly, the second element could also be termed the first element.

Each of the features of the various embodiments of the present disclosure may be combined or combined with each other, in part or in whole, and technically various interlocking and driving are possible. Each embodiment may be implemented independently of each other or may be implemented together in an association.

Hereinafter, embodiments will be described with reference to the accompanying drawings.

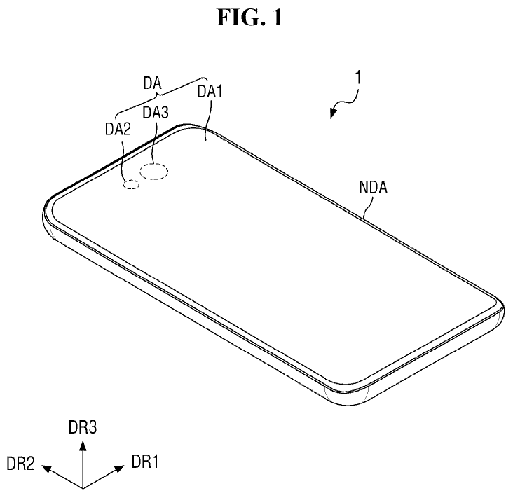

FIG. 1 is a schematic perspective view of an electronic device according to an embodiment.

Referring to FIG. 1, an electronic device 1 displays at least one moving image and/or still image. The electronic device 1 may refer to any electronic device that has a display screen applied thereto. Examples of the electronic device 1 may include a television, a laptop computer, a monitor, a billboard, an Internet-of-Things device, a mobile phone, a smartphone, a tablet personal computer (PC), an electronic watch, a smart watch, a watch phone, a head-mounted display, a mobile communication terminal, an electronic notebook, an electronic book, a portable multimedia player (PMP), a navigation device, a game machine, a digital camera, a camcorder and the like, which provide a display screen.

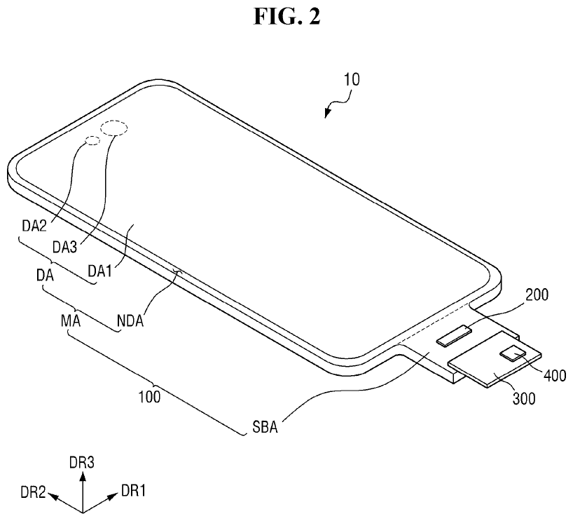

The electronic device 1 may include a display device 10 in FIG. 2 providing a display screen. Examples of the display device may include an inorganic light emitting diode display device, an organic light emitting display device, a quantum dot light emitting display device, a plasma display device and a field emission display device. In the following description, an embodiment in which an organic light emitting diode display device is applied as a display device will be described. However, embodiments of the present disclosure are not necessarily limited thereto, and other display devices may be applied.

The shape of the electronic device 1 may be variously modified. For example, the electronic device 1 may have a shape such as a rectangular shape elongated in a horizontal direction, a rectangular shape elongated in a vertical direction, a square shape, a quadrilateral shape with rounded corners (e.g., vertices), other polygonal shapes or a circular shape. In some embodiments, the shape of a display area DA of the electronic device 1 in a plan view may be similar to the overall shape of the electronic device 1 in a plan view. FIG. 1 illustrates the electronic device 1 having a rectangular shape elongated in a second direction DR2 in a plan view.

The electronic device 1 may include the display area DA and a non-display area NDA. The display area DA is an area where a screen can be displayed, and the non-display area NDA is an area where a screen is not displayed. The display area DA may also be referred to as an active region, and the non-display area NDA may also be referred to as a non-active region. In an embodiment, the display area DA may substantially occupy the center of the electronic device 1 in a plan view and the non-display area NDA may surround at least one side of the display area DA in the plan view.

In an embodiment, the display area DA may include a first display area DA1, a second display area DA2, and a third display area DA3. The second display area DA2 and the third display area DA3 are areas in which components for adding various functions to the electronic device 1 are disposed, and the second display area DA2 and the third display area DA3 may correspond to a component area.

FIG. 2 is a perspective view illustrating a display device included in an electronic device according to an embodiment.

Referring to FIG. 2, the electronic device 1 according to an embodiment may include the display device 10. The display device 10 may provide a screen displayed by the electronic device 1. In an embodiment, the display device 10 may have a planar shape similar to the planar shape of the electronic device 1. For example, in an embodiment the display device 10 may have a shape similar to a rectangular shape having a short side in a first direction DR1 and a long side in the second direction DR2. In an embodiment, the edge where the short side in the first direction DR1 and the long side in the second direction DR2 meet may be rounded to have a curvature. However, embodiments of the present disclosure are not necessarily limited thereto and the edge may be formed at a right angle in some embodiments. The planar shape of the display device 10 is not necessarily limited to a quadrilateral shape, and may be formed in a shape similar to another polygonal shape, a circular shape, or elliptical shape.

In an embodiment, the display device 10 may include a display panel 100, a display driver 200, a circuit board 300, and a touch driver 400.

The display panel 100 may include a main region MA and a sub-region SBA.

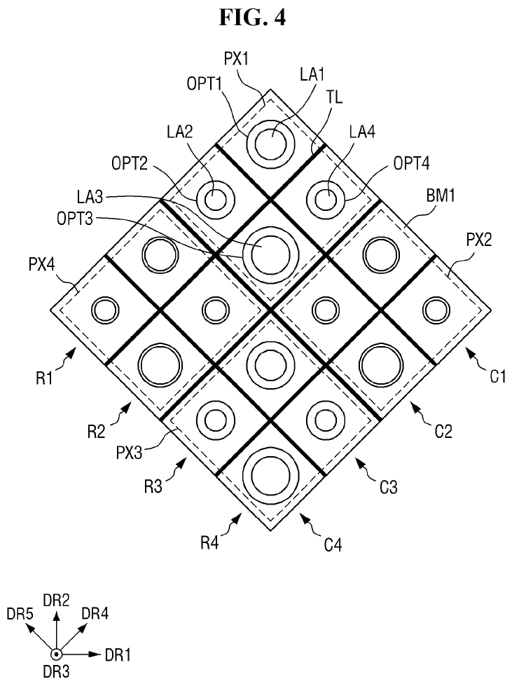

The main region MA may include the display area DA including pixels PX1, PX2, PX3, and PX4 (see FIG. 4) that display an image, and the non-display area NDA disposed around the display area DA. In an embodiment, the display area DA may be disposed in the center of the main region MA, and the non-display area NDA may surround the display area DA (e.g., in the first and/or second directions DR1, DR2). The display area DA may include the first display area DA1, the second display area DA2, and the third display area DA3. The display area DA may emit light from a plurality of emission areas or a plurality of opening areas. For example, the display panel 100 may include a pixel circuit including switching elements, a pixel defining film defining an emission area or an opening area, and a self-light emitting element.

For example, in an embodiment the self-light emitting element may include at least one of an organic light emitting diode (LED) including an organic light emitting layer, a quantum dot LED including a quantum dot light emitting layer, an inorganic LED including an inorganic semiconductor, or a micro LED. However, embodiments of the present disclosure are not necessarily limited thereto.

The non-display area NDA may be an area outside the display area DA (e.g., in a plan view). The non-display area NDA may be defined as an edge area of the main region MA of the display panel 100. In an embodiment, the non-display area NDA may include a gate driver that supplies gate signals to the gate lines, and fan-out lines that connect the display driver 200 to the display area DA.

The sub-region SBA may be a region extending from one side of the main region MA. For example, in an embodiment the sub-region SBA may extend from a lower side of the main region MA in the second direction DR2. However, embodiments of the present disclosure are not necessarily limited thereto. The sub-region SBA may include a flexible material which can be bent, folded or rolled. For example, when the sub-region SBA is bent, the sub-region SBA may overlap the main region MA in a thickness direction (e.g., the third direction DR3). The sub-region SBA may include the display driver 200 and a pad portion connected to the circuit board 300. However, embodiments of the present disclosure are not necessarily limited thereto. For example, in an embodiment, the sub-region SBA may be omitted, and the display driver 200 and the pad portion may be disposed in the non-display area NDA.

The display driver 200 may output signals and voltages for driving the display panel 100. The display driver 200 may supply data voltages to data lines. The display driver 200 may supply a power voltage to the power line and may supply a gate control signal to the gate driver. In an embodiment, the display driver 200 may be formed as an integrated circuit (IC) and mounted on the display panel 100 by a chip on glass (COG) method, a chip on plastic (COP) method, or an ultrasonic bonding method. For example, the display driver 200 may be disposed in the sub-region SBA, and may overlap the main region MA in the thickness direction (e.g., the third direction DR3) by bending of the sub-region SBA. However, embodiments of the present disclosure are not necessarily limited thereto. For example, in an embodiment the display driver 200 may be mounted on the circuit board 300.

In an embodiment, the circuit board 300 may be attached to the pad portion of the display panel 100 by using an anisotropic conductive film (ACF). Lead lines of the circuit board 300 may be electrically connected to the pad portion of the display panel 100. In an embodiment, the circuit board 300 may be a flexible printed circuit board, a printed circuit board, or a flexible film such as a chip on film.

The touch driver 400 may be mounted on the circuit board 300. The touch driver 400 may be connected to a touch sensing unit of the display panel 100. The touch driver 400 may supply a touch driving signal to a plurality of touch electrodes of the touch sensing unit and may sense an amount of change in capacitance between the plurality of touch electrodes. For example, in an embodiment the touch driving signal may be a pulse signal having a predetermined frequency. The touch driver 400 may calculate whether an input is made and input coordinates based on an amount of change in capacitance between the plurality of touch electrodes. In an embodiment, the touch driver 400 may be formed as an integrated circuit (IC).

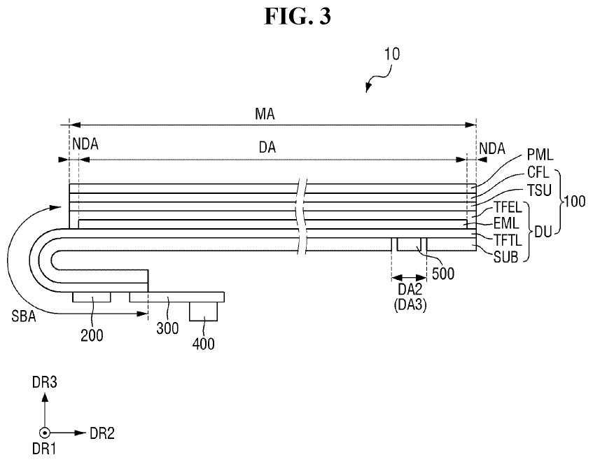

FIG. 3 is a cross-sectional view of the display device of FIG. 2 viewed from the side. FIG. 3 illustrates the sub-region SBA of the display panel 100 in a folded state in the display device 10 of FIG. 2.

Referring to FIG. 3, in an embodiment the display panel 100 may include a display layer DU, a touch sensing layer TSU, a color filter layer CFL, and a light blocking member layer PML. The display layer DU may include a substrate SUB, a thin film transistor layer TFTL, a light emitting element layer EML, and an encapsulation layer TFEL.

The substrate SUB may be a base substrate or a base member. In an embodiment, the substrate SUB may be a flexible substrate which can be bent, folded or rolled. For example, in an embodiment the substrate SUB may include a polymer resin such as polyimide (PI). However, embodiments of the present disclosure are not necessarily limited thereto. For example, in an embodiment, the substrate SUB may include a glass material or a metal material.

The thin film transistor layer TFTL may be disposed on the substrate SUB (e.g., disposed directly thereon in the third direction DR3). The thin film transistor layer TFTL may include a plurality of thin film transistors constituting a pixel circuit of pixels. The thin film transistor layer TFTL may further include gate lines, data lines, power lines, gate control lines, fan-out lines that connect the display driver 200 to the data lines, and lead lines that connect the display driver 200 to the pad portion. Each of the thin film transistors may include a semiconductor region, a source electrode, a drain electrode, and a gate electrode. For example, when the gate driver is formed on one side of the non-display area NDA of the display panel 100, the gate driver may include thin film transistors.

The thin film transistor layer TFTL may be disposed in the display area DA, the non-display area NDA, and the sub-region SBA. Thin film transistors, gate lines, data lines, and power lines of each of the pixels of the thin film transistor layer TFTL may be disposed in the display area DA. Gate control lines and fan-out lines of the thin film transistor layer TFTL may be disposed in the non-display area NDA. The lead lines of the thin film transistor layer TFTL may be disposed in the sub-region SBA.

The light emitting element layer EML may be disposed on the thin film transistor layer TFTL (e.g., disposed directly thereon in the third direction DR3). In an embodiment, the light emitting element layer EML may include a plurality of light emitting elements each including a first electrode, a second electrode, and a light emitting layer to emit light, and a pixel defining film defining pixels. The plurality of light emitting elements of the light emitting element layer EML may be disposed in the display area DA.

In an embodiment, the light emitting layer may be an organic light emitting layer including an organic material. The light emitting layer may include a hole transporting layer, an organic light emitting layer, and an electron transporting layer. When the first electrode receives a voltage through the thin film transistor of the thin film transistor layer TFTL and the second electrode receives the cathode voltage, holes and electrons may be transferred to the organic light emitting layer through the hole transporting layer and the electron transporting layer, respectively and may be combined with each other to emit light in the organic light emitting layer.

However, embodiments of the present disclosure are not necessarily limited thereto. For example, in an embodiment, the light emitting elements may include a quantum dot light emitting diode including a quantum dot light emitting layer, an inorganic light emitting diode including an inorganic semiconductor, or a micro light emitting diode.

The encapsulation layer TFEL may cover the top surface and the side surface of the light emitting element layer EML, and may protect the light emitting element layer EML. In an embodiment, the encapsulation layer TFEL may include at least one inorganic film and at least one organic film for encapsulating the light emitting element layer EML.

The touch sensing layer TSU may be disposed on the encapsulation layer TFEL (e.g., disposed directly thereon in the third direction DR3). The touch sensing layer TSU may include a plurality of touch electrodes for sensing a user's touch in a capacitive manner, and touch lines connecting the plurality of touch electrodes to the touch driver 400. For example, the touch sensing layer TSU may sense the user's touch by using a mutual capacitance method or a self-capacitance method.

However, embodiments of the present disclosure are not necessarily limited thereto. For example, in an embodiment, the touch sensing layer TSU may be disposed on a separate substrate disposed on the display layer DU. In this embodiment, the substrate supporting the touch sensing layer TSU may be a base member that encapsulates the display layer DU.

The plurality of touch electrodes of the touch sensing layer TSU may be disposed in a touch sensor area overlapping the display area DA. The touch lines of the touch sensing layer TSU may be disposed in a touch peripheral area that overlaps the non-display area NDA.

The color filter layer CFL may be disposed on the touch sensing layer TSU (e.g., disposed directly thereon in the third direction DR3). The color filter layer CFL may include a plurality of color filters respectively corresponding to the plurality of emission areas. In an embodiment, each of the color filters may selectively transmit light of a specific wavelength and may block or absorb light of a different wavelength. The color filter layer CFL may absorb a portion of light coming from the outside of the display device 10 (e.g., the external environment) to reduce reflected light due to external light. Accordingly, the color filter layer CFL may prevent color distortion caused by reflection of the external light.

In an embodiment in which the color filter layer CFL is directly disposed on the touch sensing layer TSU, the display device 10 may not require a separate substrate for the color filter layer CFL. Accordingly, the thickness of the display device 10 may be relatively small.

The light blocking member layer PML may be disposed on the color filter layer CFL (e.g., disposed directly thereon in the third direction DR3). In an embodiment, the light blocking member layer PML may include light blocking patterns disposed to correspond to specific pixels of the display layer DU. The display device 10 may further include the light blocking member layer PML to control visibility at a specific viewing angle and provide a privacy protection mode to the user.

In some embodiments, the display device 10 may further include an optical device 500. The optical device 500 may be disposed in the second display area DA2 or the third display area DA3. The optical device 500 may emit or receive light in infrared, ultraviolet, and visible light bands. For example, in an embodiment the optical device 500 may be an optical sensor that detects light incident on the display device 10 such as a proximity sensor, an illuminance sensor, and a camera sensor or an image sensor.

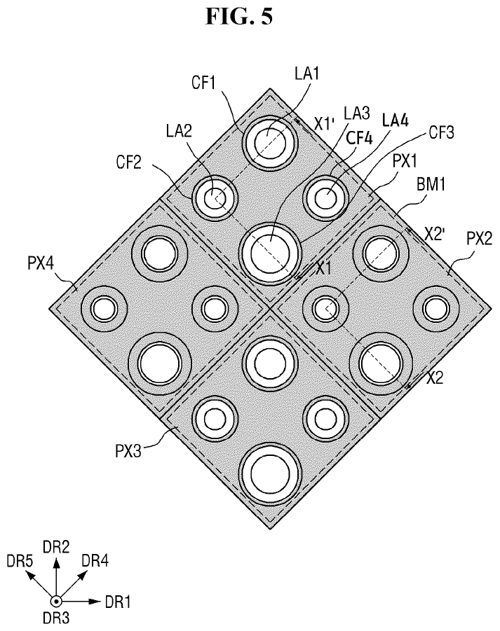

FIG. 4 is a plan view of the arrangement of pixel electrodes in the display area of the display device according to an embodiment. FIG. 5 is a plan view illustrating the arrangement of a pixel electrode, a first light blocking layer, and color filters in a display area of a display device according to an embodiment.

Referring to FIGS. 4 and 5, the display device 10 may include a plurality of pixels PX1, PX2, PX3, and PX4 disposed in the display area DA. In an embodiment, the plurality of pixels PX1, PX2, PX3, and PX4 may be arranged in a fourth direction DR4 and a fifth direction DR5, which are diagonal directions between the first direction DR1 and the second direction DR2. The first pixel PX1 and the second pixel PX2 may be disposed adjacent to each other in the fifth direction DR5, and the second pixel PX2 and the third pixel PX3 may be disposed adjacent to each other in the fourth direction DR4. The third pixel PX3 and the fourth pixel PX4 may be disposed adjacent to each other in the fifth direction DR5. In an embodiment, the plurality of pixels PX1, PX2, PX3, and PX4 may be repeatedly disposed in the arrangement of FIG. 4 over the entire display area DA.

Each of the plurality of pixels PX1, PX2, PX3, and PX4 may include a plurality of emission areas LA1, LA2, LA3, and LA4. For example, each of the pixels PX1, PX2, PX3, and PX4 may include a first emission area LA1, a second emission area LA2, a third emission area LA3, and a fourth emission area LA4. However, embodiments of the present disclosure are not necessarily limited thereto. The number of emission areas LA1, LA2, LA3, and LA4 disposed in the pixels PX1, PX2, PX3, and PX4 and the arrangements thereof may be variously modified.

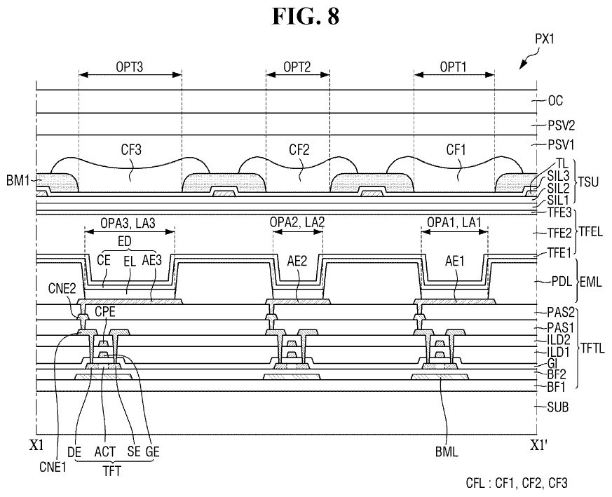

One pixel PX1, PX2, PX3, PX4 may include one or more light emitting elements ED (see FIG. 8), and the light emitting elements may be light emitting elements that emit light of different colors. For example, in an embodiment a light emitting element including the first emission area LA1 may emit first light of a red color. A light emitting element including the second emission area LA2 may emit second light of a green color, and a light emitting element including the third emission area LA3 may emit third light of a blue color. In addition, the light emitting element including the fourth emission area LA4 may emit second light of a green color. However, embodiments of the present disclosure are not necessarily limited thereto and the colors emitted by the light emitting elements in the emission areas may be variously modified.

Each of the emission areas LA1, LA2, LA3, and LA4 may emit light of various colors. For example, in an embodiment the first emission area LA1 may emit the first light of the red color, the second emission area LA2 may emit the second light of the green color, the third emission area LA3 may emit the third light of the blue color, and the fourth emission area LA4 may emit the second light of the green color. In an embodiment, each emission area LA1, LA2, LA3, LA4 of the display device 10 may be an area overlapping a pixel electrode. For example, openings OPA1, OPA2, and OPA3 of a pixel defining film PDL illustrated in FIG. 8 may correspond to the emission areas LA1, LA2, LA3, and LA4. For example, the emission areas LA1, LA2, LA3, and LA4 may be defined by the plurality of openings OPA1, OPA2, and OPA3 formed in the pixel defining film PDL (see FIG. 8) of the light emitting element layer EML, which will be described later. In an embodiment, the first emission area LA1 may be defined by the first opening OPA1 of the pixel defining film that overlaps a first pixel electrode AE1, the second emission area LA2 may be defined by the second opening OPA2 of the pixel defining film that overlaps a second pixel electrode AE2, and the third emission area LA3 may be defined by the third opening OPA3 of the pixel defining film that overlaps a third pixel electrode AE3. In an embodiment, the fourth emission area LA4 may be defined by a fourth opening that overlaps a fourth pixel electrode of the pixel defining film.

In an embodiment, the plurality of emission areas LA1, LA2, LA3, and LA4 may be disposed in a PenTile™ type, for example, a diamond PenTile™ type. For example, the first emission area LA1 and the third emission area LA3 may be spaced apart from each other in the second direction DR2, and they may be alternately disposed in the first direction DR1 and the second direction DR2. The second emission area LA2 and the fourth emission area LA4 may be spaced apart from emission area in the first direction DR1 and the second direction DR2, and may be spaced apart from the adjacent first emission area LA1 and the adjacent third emission area LA3 in the fourth direction DR4 or the fifth direction DR5. The second emission area LA2 and the fourth emission area LA4 may be repeatedly disposed along the first direction DR1 and the second direction DR2, and the second emission area LA2 and the first emission area LA1, or the fourth emission area LA4 and the third emission area LA3 may be alternately disposed along the fourth direction DR4 or the fifth direction DR5.

In an embodiment, the areas or sizes of the first to fourth emission areas LA1, LA2, LA3, and LA4 may be different from each other. In an embodiment shown in FIG. 4, the area of the third emission area LA3 may be greater than the areas of the first emission area LA1, the second emission area LA2, and the fourth emission area LA4, and the area of the first emission area LA1 may be greater than the areas of the second emission area LA2 and the fourth emission area LA4. The intensity of light emitted may vary according to the areas of the emission areas LA1, LA2, LA3, and LA4, and the areas of the emission areas LA1, LA2, LA3, and LA4 may be adjusted to control the color of the screen displayed on the display device 10 or the electronic device 1. In an embodiment shown in FIG. 4, the third emission area LA3 having the largest area is illustrated. However, embodiments of the present disclosure are not necessarily limited thereto. The sizes of the emission areas LA1, LA2, LA3, and LA4 and the areas of the emission areas may be variously adjusted depending on the color of the screen required in the display device 10 or the electronic device 1. In addition, the areas of the emission areas LA1, LA2, LA3, and LA4 may be related to light efficiency and the lifespan of the light emitting element ED, and may have a trade-off relationship with the reflection by external light. The areas of the emission areas LA1, LA2, LA3, and LA4 may be adjusted in consideration of the above factors.

The display device 10 may include a first light blocking layer BM1 and a plurality of color filters CF1, CF2, CF3, and CF4 disposed on the emission areas LA1, LA2, LA3, and LA4.

In an embodiment, the first light blocking layer BM1 may be disposed over the entire display area DA. In an embodiment, the first light blocking layer BM1 may include a plurality of holes OPT1, OPT2, OPT3, and OPT4 disposed to correspond to the plurality of emission areas LA1, LA2, LA3, and LA4, respectively. In an embodiment, the holes OPT1, OPT2, OPT3, and OPT4 of the first light blocking layer BM1 may be disposed to correspond to the openings OPA1, OPA2, OPA3, and OPA4 in the pixel defining film PDL (see FIG. 8), respectively. The first light blocking layer BM1 may cover the display area DA except for a region where the holes OPT1, OPT2, OPT3, and OPT4 are disposed in the display area DA. The holes OPT1, OPT2, OPT3, and OPT4 of the first light blocking layer BM1 may be areas through which light emitted from the light emitting elements corresponding to the respective emission areas LA1, LA2, LA3, and LA4 is outputted. In an embodiment, the plurality of holes OPT1, OPT2, OPT3, and OPT4 may include the first hole OPT1 overlapping the first emission area LA1, the second hole OPT2 overlapping the second emission area LA2, the third hole OPT3 overlapping the third emission area LA3, and the fourth hole OPT4 overlapping the fourth emission area LA4.

The areas of the plurality of holes OPT1, OPT2, OPT3, and OPT4 in a plan view may be larger than the areas of the emission areas LA1, LA2, LA3, and LA4 in a plan view, respectively. For example, the first hole OPT1 may have a larger area in the plan view than the first emission area LA1. The second hole OPT2 may have a larger area in the plan view than the second emission area LA2. The third hole OPT3 may have a larger area in the plan view than the third emission area LA3. The fourth hole OPT4 may have a larger area in the plan view than the fourth emission area LA4.

In addition, the holes OPT1, OPT2, OPT3, and OPT4 of the first light blocking layer BM1 may have different areas from each other in a plan view. As described above, the areas of the plurality of emission areas LA1, LA2, LA3, and LA4 may be different from each other, and accordingly, the sizes of the holes OPT1, OPT2, OPT3, and OPT4 of the first light blocking layer BM1 may also be different from each other. For example, in an embodiment the diameter or size of the third hole OPT3 may be larger than those of the first hole OPT1, the second hole OPT2, and the fourth hole OPT4, and the diameter or size of the first hole OPT1 may be larger than those of the second hole OPT2 and the fourth hole OPT4. However, embodiments of the present disclosure are not necessarily limited thereto.

In an embodiment, the difference between the diameter of the emission area LA1, LA2, LA3, LA4 and the diameter of the hole OPT1, OPT2, OPT3, OPT4 of the first light blocking layer BM1 in the same pixel PX1, PX2, PX3, PX4, or the separation distance between the inner side surface of the opening OPA1, OPA2, OPA3, OPA4 and the inner side surface of the hole OPT1, OPT2, OPT3, OPT4 may be uniform regardless of the type of the emission areas LA1, LA2, LA3, and LA4 or the holes OPT1, OPT2, OPT3, and OPT4. For example, the separation distance between the first emission area LA1 and the first hole OPT1, or the difference between the diameter of the first emission area LA1 and the diameter of the first hole OPT1 may be equal to the separation distance between the second emission area LA2 and the second hole OPT2, or the difference between the diameter of the second emission area LA2 and the diameter of the second hole OPT2. The separation distance or the diameter difference may also be equal to the separation distance between the third emission area LA3 and the third hole OPT3, or the difference between the diameter of the third emission area LA3 and the diameter of the third hole OPT3, and may also be equal to the separation distance between the fourth emission area LA4 and the fourth hole OPT4, or the difference between the diameter of the fourth emission area LA4 and the diameter of the fourth hole OPT4. However, embodiments of the present disclosure are not necessarily limited thereto, and the respective separation distances between the emission areas LA1, LA2, LA3, and LA4 and the holes OPT1, OPT2, OPT3, and OPT4 of the first light blocking layer BM1 may vary from each other in some embodiments.

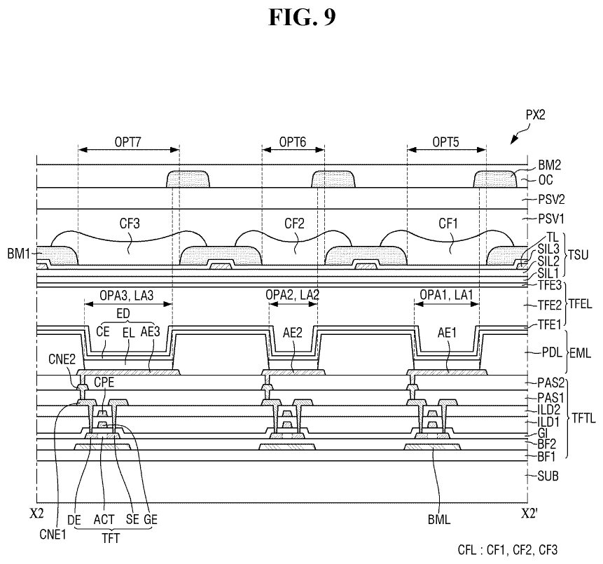

According to an embodiment, the display device 10 may include the pixels PX1, PX2, PX3, and PX4 having different separation distances between the emission areas LA1, LA2, LA3, and LA4 and the holes OPT1, OPT2, OPT3, and OPT4 of the first light blocking layer BM1. For example, in the first pixel PX1 and the third pixel PX3, the respective separation distances between the emission areas LA1, LA2, LA3, and LA4 and the holes OPT1, OPT2, OPT3, and OPT4 of the first light blocking layer BM1 may be equal to each other. Also in the second pixel PX2 and the fourth pixel PX4, the respective separation distances between the emission areas LA1, LA2, LA3, and LA4 and the holes OPT5, OPT6, OPT7, and OPT8 (see FIG. 9) of the first light blocking layer BM1 may be equal to each other. However, in the first pixel PX1 and the second pixel PX2, the separation distances between the emission areas LA1, LA2, LA3, and LA4 and the holes OPT1 to OPT4 and OPT5 to OPT8 of the first light blocking layer BM1 may be different from each other. In an embodiment, the respective separation distance between the emission areas LA1, LA2, LA3, and LA4 and the holes OPT1, OPT2, OPT3, and OPT4 of the first light blocking layer BM1 in the first pixel PX1 and the third pixel PX3 may be greater than the respective separation distance between the emission areas LA1, LA2, LA3, and LA4 and the holes OPT5, OPT6, OPT7, and OPT8 of the first light blocking layer BM1 in the second pixel PX2 and the fourth pixel PX4. In the second pixel PX2 and the fourth pixel PX4, the diameter difference between the emission areas LA1, LA2, LA3, and LA4 and the holes OPT5, OPT6, OPT7, and OPT8 of the first light blocking layer BM1 may be relatively small, and the inner side surfaces of the openings OPA5, OPA6, OPA7, and OPA8 and the inner side surfaces of the holes OPT5, OPT6, OPT7, and OPT8 may be located adjacent to each other in the plan view.

In an embodiment, the display device 10 may include a portion of pixels (e.g., a second portion of pixels) having a first type pixel such as the first pixel PX1 and the third pixel PX3, and a portion of pixels (e.g., a first portion of pixels) having a second type pixel such as the second pixel PX2 and the fourth pixel PX4. The distinction between the first type pixel and the second type pixel may be made not only by the respective separation distance between the emission areas LA1, LA2, LA3, and LA4 and the holes OPT1, OPT2, OPT3, and OPT4 of the first light blocking layer BM1, but also by the presence/absence of a second light blocking layer BM2 to be described later. For example, in an embodiment the second light blocking layer BM2 may not be disposed in the first pixel PX1 and the third pixel PX3, and the second light blocking layer BM2 may be disposed in the second pixel PX2 and the fourth pixel PX4. The second light blocking layer BM2 will be described later with reference to other drawings.

The plurality of color filters CF1, CF2, CF3, and CF4 may be disposed to correspond to the emission areas LA1, LA2, LA3, and LA4, respectively. For example, the color filters CF1, CF2, CF3, and CF4 may be disposed on the first light blocking layer BM1 and may be disposed to correspond to the plurality of holes OPT1, OPT2, OPT3, and OPT4 of the first light blocking layer BM1. The holes OPT1, OPT2, OPT3, and OPT4 of the first light blocking layer BM1 may be formed to overlap the openings OPA1, OPA2, OPA3, and OPA4 of the pixel defining film PDL (see FIG. 8), and may form a light exit area through which light emitted from the emission areas LA1, LA2, LA3, and LA4 is outputted. In an embodiment, the color filters CF1, CF2, CF3, and CF4 may have areas (e.g., in a plan view) larger than those of the holes OPT1, OPT2, OPT3, and OPT4 of the first light blocking layer BM1, respectively, and the color filters CF1, CF2, CF3, and CF4 may completely cover the light exit area formed by the holes OPT1, OPT2, OPT3, and OPT4, respectively. The color filters CF1, CF2, CF3, and CF4 may completely cover the holes OPT1, OPT2, OPT3, and OPT4 of the first light blocking layer BM1, respectively, and a portion thereof may be disposed directly on the first light blocking layer BM1. However, embodiments of the present disclosure are not necessarily limited thereto. For example, in some embodiments, the color filters CF1, CF2, CF3, and CF4 may be omitted.

In an embodiment, the color filters CF1, CF2, CF3, and CF4 may include a first color filter CF1, a second color filter CF2, a third color filter CF3, and a fourth color filter CF4 disposed to correspond to the different emission areas LA1, LA2, LA3, and LA4, respectively. The color filters CF1, CF2, CF3, and CF4 may include a colorant such as a dye or a pigment that absorbs light in a wavelength band and does not absorb light in a specific wavelength band, and may be disposed to correspond to the color of the light emitted from the light emitting element including the emission areas LA1, LA2, LA3, and LA4. For example, in an embodiment the first color filter CF1 may be a red color filter that is disposed to overlap the first emission area LA1 and transmits only the first light of the red color. The second color filter CF2 may be a green color filter that is disposed to overlap the second emission area LA2 and transmits only the second light of the green color, the third color filter CF3 may be a blue color filter that is disposed to overlap the third emission area LA3 and transmits only the third light of the blue color, and the fourth color filter CF4 may be a green color filter that is disposed to overlap the fourth emission area LA4 and transmits only the second light of the green color.

Similarly to the arrangement of the emission areas LA1, LA2, LA3, and LA4, the color filters CF1, CF2, CF3, and CF4 may be disposed in a PenTile™ type, for example, a diamond PenTile™ type. For example, in an embodiment the first color filter CF1 and the third color filter CF3 may be alternately disposed in the first direction DR1 and the second direction DR2. The second color filter CF2 and the fourth color filter CF4 may be arranged in the first direction DR1 and the second direction DR2, and the second color filter CF2 and the adjacent first color filter CF1 and the adjacent third color filter CF3 may be arranged in the fourth direction DR4 or the fifth direction DR5. In an embodiment, the second color filter CF2 and the fourth color filter CF4 may be repeatedly arranged along the first direction DR1 and the second direction DR2, and the second color filter CF2 and the first color filter CF1, or the fourth color filter CF4 and the third color filter CF3 may be alternately arranged along the fourth direction DR4.

According to an embodiment, the plurality of color filters CF1, CF2, CF3, and CF4 may have different areas from each other in a plan view. As described above, the areas of the plurality of emission areas LA1, LA2, LA3, and LA4 may be different from each other, and accordingly, the sizes of the holes OPT1, OPT2, OPT3, and OPT4 of the first light blocking layer BM1 and the areas of the color filters CF1, CF2, CF3, and CF4 in the plan view may also be different from each other. For example, in an embodiment the area of the first color filter CF1, which is a red color filter, may be larger than the areas of the second color filter CF2 and the fourth color filter CF4, which are green color filters, and the third color filter CF3, which is a blue color filter. Additionally, the area of the third color filter CF3 may be larger than the areas of the second color filter CF2 and the fourth color filter CF4. In an embodiment, the shape of the color filters CF1, CF2, CF3, and CF4 in the plan view may be a circular shape similar to the shape of the emission areas LA1, LA2, LA3, and LA4. However, embodiments of the present disclosure are not necessarily limited thereto, and the color filters CF1, CF2, CF3, and CF4 may have a rectangular or rhombic shape in the plan view in some embodiments. The display device 10 according to an embodiment may be designed such that the planar shape and area of the color filters CF1, CF2, CF3, and CF4 allow external light of the display device 10 to have a specific color.

In an embodiment, the planar area ratio of the first color filter CF1 and the second color filter CF2 or the first color filter CF1 and the fourth color filter CF4 may be in a range from about 1:0.3 to about 1:0.7. The area ratio of the first color filter CF1 and the third color filter CF3 may be in a range from about 1:0.4 to about 1:1. For example, the area ratio of the first color filter CF1, the second color filter CF2 (or the fourth color filter CF4) and the third color filter CF3 may be about 1:0.59:0.52 or about 1:0.59:1. However, the area ratio of the color filters CF1, CF2, CF3, and CF4 is not necessarily limited to the above-described, and the planar areas of the color filters CF1, CF2, CF3, and CF4 may be designed differently such that the reflected light in the display device 10 and the electronic device 1 has desired color coordinates.

The display device 10 may include the color filters CF1, CF2, CF3, and CF4 disposed on the display layer DU to reduce the intensity of reflected light caused by external light. Furthermore, the color of the reflected light by the external light may be controlled by adjusting the arrangement, shape, and area of the color filters CF1, CF2, CF3, and CF4 in the plan view. A detailed description thereof will be given later with reference to other drawings.

In an embodiment, a touch electrode TL may be disposed between the emission areas LA1, LA2, LA3, and LA4. The touch electrode TL may be disposed to extend in the fourth direction DR4 and the fifth direction DR5, and may be spaced apart from the emission areas LA1, LA2, LA3, and LA4. The touch electrode TL may be disposed to overlap the pixel defining film PDL (see FIG. 8) and the first light blocking layer BM1. Although the touch electrode TL is briefly illustrated in the drawing, the touch electrode TL may include a touch driving electrode and a sensing electrode.

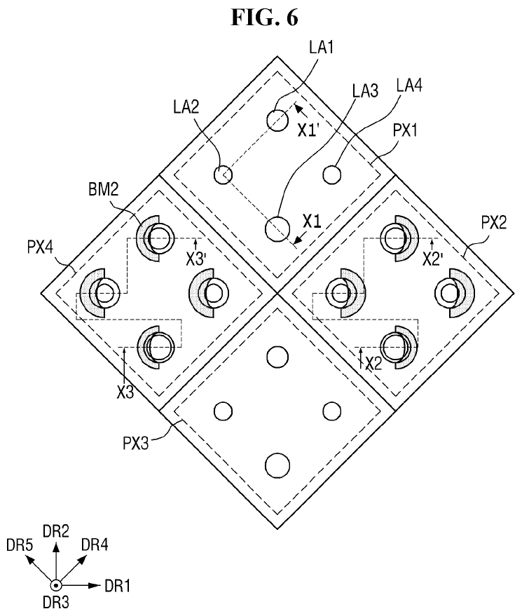

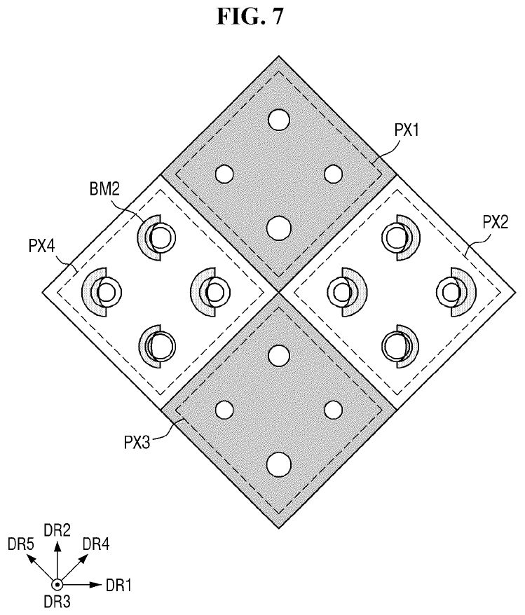

FIG. 6 is a plan view of the arrangement of the emission areas and the second light blocking layer in the display area of the display device according to an embodiment. FIG. 7 is a schematic diagram illustrating light emitting pixels according to an emission mode of the display device according to an embodiment. FIG. 7 schematically illustrates the light emitting pixels in an emission mode with partially restricted side visibility among the emission modes of the display device 10.

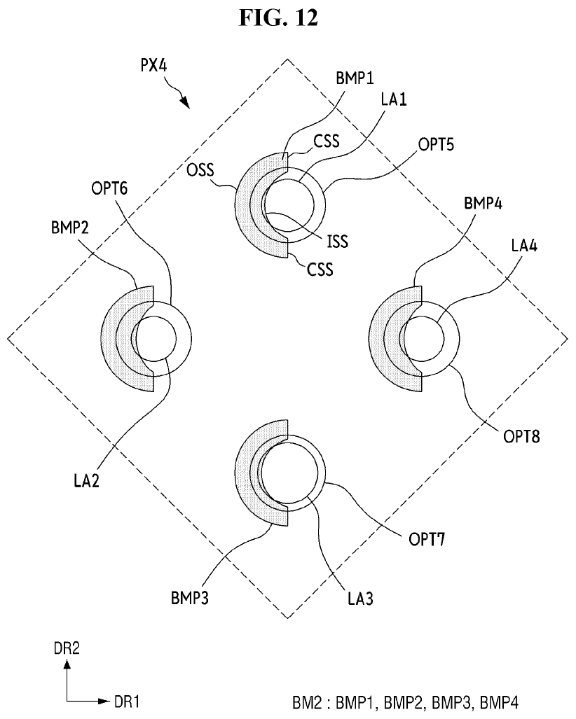

Referring to FIGS. 6 and 7, the display device 10 according to an embodiment may include the second light blocking layer BM2. The second light blocking layer BM2 may be disposed only in some of the plurality of pixels in the display area DA. For example, in an embodiment the second light blocking layer BM2 may be disposed in the second type pixel, such as the second pixel PX2 and the fourth pixel PX4, of the plurality of pixels PX. As described above, the plurality of pixels PX may include two types of pixels with different respective separation distances between the emission areas LA1, LA2, LA3, and LA4 and the holes OPT1, OPT2, OPT3, and OPT4 of the first light blocking layer BM1, and the second light blocking layer BM2 may be disposed only in the second type pixel. For example, a plurality of light blocking patterns (BMP1, BMP2, BMP3, and BMP4 in FIG. 12) of the second light blocking layer BM2 may not overlap the first type pixel such as the first pixel PX1 and the third pixel PX3 (e.g., in the third direction DR3), and may overlap the second type pixel such as the second pixel PX2 and the fourth pixel PX4 (e.g., in the third direction DR3).

In an embodiment, the second light blocking layer BM2 may include the plurality of light blocking patterns (BMP1, BMP2, BMP3, and BMP4 in FIG. 12), and the light blocking patterns may be disposed to correspond to the plurality of emission areas LA1, LA2, LA3, and LA4, respectively. For example, the light blocking patterns may be disposed to overlap the emission areas LA1, LA2, LA3, and LA4 while surrounding portions of the emission areas LA1, LA2, LA3, and LA4 in the plan view. In an embodiment, the light blocking patterns may have a semi-ring shape that covers a portion of each emission area LA1, LA2, LA3, LA4 while surrounding it in the plan view. Similarly to the holes OPT1, OPT2, OPT3, and OPT4 of the first light blocking layer BM1, the inner side surfaces of the light blocking patterns may be spaced apart from the inner side surface of the pixel defining film PDL (see FIG. 8) in the plan view.

In the display device 10 according to an embodiment, the plurality of pixels PX may include the first type pixel in which the second light blocking layer BM2 is not disposed and the second type pixel in which the second light blocking layer BM2 is disposed, so that the side visibility may be adjusted depending on the emission mode. In an embodiment, depending on the viewing angle of the display device 10, the light blocking patterns of the second light blocking layer BM2 may partially cover the emission areas LA1, LA2, LA3, and LA4, and may block the emission of light at a specific viewing angle.

For example, in a first emission mode of the display device 10, when the side visibility is not restricted, both the first type pixel and the second type pixel may emit light. For example, as shown in FIG. 6, when all of the first to fourth pixels PX1, PX2, PX3, and PX4 emit light in the first emission mode, light emitted from at least the first pixel PX1 and the third pixel PX3 may be visually recognized by the user, regardless of which direction the user looks at the display device 10.

On the other hand, in a second emission mode of the display device 10, when it is required to restrict the side visibility, only the second type pixel may emit light. For example, as illustrated in FIG. 7, when only the second pixel PX2 and the fourth pixel PX4 emit light in the second emission mode, light emitted from the holes OPT1, OPT2, OPT3, and OPT4 of the first light blocking layer BM1 may be blocked by the second light blocking layer BM2 at a specific viewing angle. For example, in an embodiment, in the second pixel PX2, among the lights emitted from the holes OPT1, OPT2, OPT3, and OPT4 of the first light blocking layer BM1, light emitted to the upper right side may be blocked by the second light blocking layer BM2. In the fourth pixel PX4, among the lights emitted from the holes OPT1, OPT2, OPT3, and OPT4 of the first light blocking layer BM1, light emitted to the upper left side may be blocked by the second light blocking layer BM2. Since the first pixel PX1 and the third pixel PX3 do not emit light, the screen of the display device 10 in the second emission mode may be visually recognized only by the user looking from the front of the display area DA, and may not be visually recognized by the user looking at a specific viewing angle or from the side. The display device 10 may provide a privacy protection mode to the user.

In addition, in the display device 10, since the light blocking patterns of the second light blocking layer BM2 are disposed to correspond to the emission areas LA1, LA2, LA3, and LA4 of the second type pixel, the light blocking patterns may not overlap other adjacent pixels, such as the first type pixel, and thus may not cover the emission areas LA1, LA2, LA3, and LA4 of the first type pixel in the first emission mode. For example, in the display device 10, the arrangement of the pixel structure may be freely designed even in the implementation of a high-resolution display device.

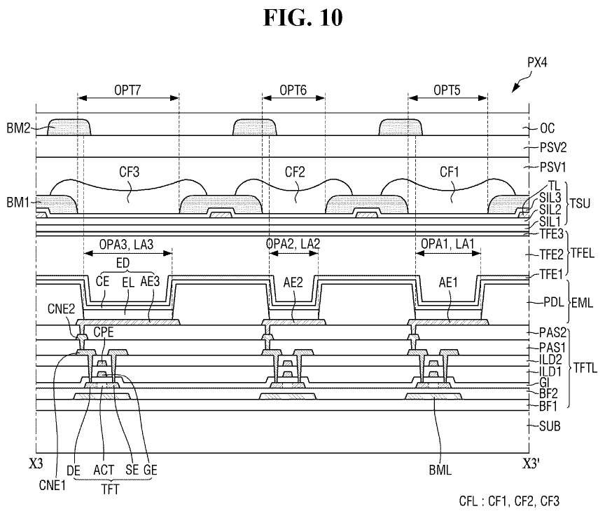

FIG. 8 is a cross-sectional view taken along line X1-X1′ of FIGS. 5 and 6. FIG. 9 is a cross-sectional view taken along line X2-X2′ of FIG. 6. FIG. 10 is a cross-sectional view taken along line X3-X3′ of FIG. 6.

FIG. 8 shows a cross-sectional view across the first to third emission areas LA1, LA2, and LA3 in the first pixel PX1 which is the first type pixel. FIG. 9 shows a cross-sectional view across the first to third emission areas LA1, LA2, and LA3 in the second pixel PX2 which is the second type pixel. FIG. 10 shows a cross-sectional view across the first to third emission areas LA1, LA2, and LA3 in the fourth pixel PX4 which is the second type pixel. Since the fourth emission area LA4 of each pixel type has the same structure as that of the second emission area LA2, a repeated explanation is omitted from FIGS. 8 to 10 for economy of explanation.

A cross-sectional structure of the display device 10 will be described with reference to FIGS. 8 to 10. In an embodiment, the display panel 100 of the display device 10 may include the display layer DU, the touch sensing layer TSU, the first light blocking layer BM1, the color filter layer CFL, and the second light blocking layer BM2. The display layer DU may include the substrate SUB, the thin film transistor layer TFTL, the light emitting element layer EML, and the encapsulation layer TFEL. The first light blocking layer BM1 may be disposed on (e.g., disposed directly thereon) the touch sensing layer TSU of the display panel 100, and the color filters CF1, CF2, and CF3 of the color filter layer CFL may be disposed on (e.g., disposed directly thereon) the first light blocking layer BM1. In an embodiment, the second light blocking layer BM2 may be disposed on passivation layers PSV1 and PSV2 disposed on the color filter layer CFL, and an overcoat layer OC may be disposed on (e.g., disposed directly thereon) the second light blocking layer BM2.

The substrate SUB may be a base substrate or a base member. The substrate SUB may be a flexible substrate which can be bent, folded or rolled. For example, in an embodiment the substrate SUB may include a polymer resin such as polyimide (PI). However, embodiments of the present disclosure are not necessarily limited thereto. For example, in an embodiment the substrate SUB may include a glass material or a metal material.

In an embodiment, the thin film transistor layer TFTL may include a first buffer layer BF1, a lower metal layer BML, a second buffer layer BF2, a thin film transistor TFT, a gate insulating layer GI, a first interlayer insulating layer ILD1, a capacitor electrode CPE, a second interlayer insulating layer ILD2, a first connection electrode CNE1, a first passivation layer PAS1, a second connection electrode CNE2, and a second passivation layer PAS2.

The first buffer layer BF1 may be disposed on the substrate SUB (e.g., disposed directly thereon in the third direction DR3). In an embodiment, the first buffer layer BF1 may include an inorganic film capable of preventing penetration of air or moisture. For example, the first buffer layer BF1 may include a plurality of inorganic films alternately stacked.

The lower metal layer BML may be disposed on the first buffer layer BF1 (e.g., disposed directly thereon in the third direction DR3). For example, in an embodiment the lower metal layer BML may be formed as a single layer or multiple layers made of any one of molybdenum (Mo), aluminum (Al), chromium (Cr), gold (Au), titanium (Ti), nickel (Ni), neodymium (Nd) and copper (Cu) or an alloy thereof.

The second buffer layer BF2 may cover the first buffer layer BF1 and the lower metal layer BML. In an embodiment, the second buffer layer BF2 may include an inorganic film capable of preventing penetration of air or moisture. For example, the second buffer layer BF2 may include a plurality of inorganic films alternately stacked.

The thin film transistor TFT may be disposed on the second buffer layer BF2, and may constitute a pixel circuit of each of a plurality of pixels. For example, the thin film transistor TFT may be a switching transistor or a driving transistor of the pixel circuit. In an embodiment, the thin film transistor TFT may include a semiconductor layer ACT, a source electrode SE, a drain electrode DE, and a gate electrode GE.

The semiconductor layer ACT may be disposed on the second buffer layer BF2 (e.g., disposed directly thereon in the third direction DR3). The semiconductor layer ACT may overlap the lower metal layer BML and the gate electrode GE in the thickness direction (e.g., the third direction DR3), and may be insulated from the gate electrode GE by the gate insulating layer GI. In a portion of the semiconductor layer ACT, a material of the semiconductor layer ACT may include impurities to be made into a conductor to form the source electrode SE and the drain electrode DE.

The gate electrode GE may be disposed on the gate insulating layer GI (e.g., disposed directly thereon in the third direction DR3). The gate electrode GE may overlap the semiconductor layer ACT with the gate insulating layer GI interposed therebetween (e.g., in the third direction DR3).

The gate insulating layer GI may be disposed on (e.g., disposed directly thereon) the semiconductor layer ACT. For example, the gate insulating layer GI may cover the semiconductor layer ACT and the second buffer layer BF2 to insulate the gate electrode GE from the semiconductor layer ACT. In an embodiment, the gate insulating layer GI may include a contact hole through which the first connection electrode CNE1 passes.

The first interlayer insulating layer ILD1 may cover the gate electrode GE and the gate insulating layer GI. In an embodiment, the first interlayer insulating layer ILD1 may include a contact hole through which the first connection electrode CNE1 passes. The contact hole of the first interlayer insulating layer ILD1 may be connected to the contact hole of the gate insulating layer GI and the contact hole of the second interlayer insulating layer ILD2.

The capacitor electrode CPE may be disposed on the first interlayer insulating layer ILD1 (e.g., disposed directly thereon in the third direction DR3). The capacitor electrode CPE may overlap the gate electrode GE in the thickness direction (e.g., in the third direction DR3). The capacitor electrode CPE and the gate electrode GE may form a capacitance.

The second interlayer insulating layer ILD2 may cover the capacitor electrode CPE and the first interlayer insulating layer ILD1. In an embodiment, the second interlayer insulating layer ILD2 may include a contact hole through which the first connection electrode CNE1 passes. The contact hole of the second interlayer insulating layer ILD2 may be connected to the contact hole of the first interlayer insulating layer ILD1 and the contact hole of the gate insulating layer GI.

The first connection electrode CNE1 may be disposed on the second interlayer insulating layer ILD2 (e.g., disposed directly thereon in the third direction DR3). The first connection electrode CNE1 may electrically connect the drain electrode DE of the thin film transistor TFT to the second connection electrode CNE2. In an embodiment, the first connection electrode CNE1 may extend in a contact hole provided in the second interlayer insulating layer ILD2, the first interlayer insulating layer ILD1, and the gate insulating layer GI to be in direct contact with the drain electrode DE of the thin film transistor TFT.

The first passivation layer PAS1 may cover the first connection electrode CNE1 and the second interlayer insulating layer ILD2. The first passivation layer PAS1 may protect the thin film transistor TFT. In an embodiment, the first passivation layer PAS1 may include a contact hole through which the second connection electrode CNE2 passes.

The second connection electrode CNE2 may be disposed on the first passivation layer PAS1 (e.g., disposed directly thereon in the third direction DR3). The second connection electrode CNE2 may electrically connect the first connection electrode CNE1 to a pixel electrode AE of the light emitting element ED. In an embodiment, the second connection electrode CNE2 may extend in a contact hole formed in the first passivation layer PAS1 to be in direct contact with the first connection electrode CNE1.

The second passivation layer PAS2 may cover the second connection electrode CNE2 and the first passivation layer PAS1. The second passivation layer PAS2 may include a contact hole through which the pixel electrode AE of the light emitting element ED passes.

The light emitting element layer EML may be disposed on the thin film transistor layer TFTL (e.g., disposed directly thereon in the third direction DR3). The light emitting element layer EML may include the light emitting element ED and the pixel defining film PDL. The light emitting element ED may include the pixel electrodes AE1, AE2, and AE3, a light emitting layer EL, and a common electrode CE.

The pixel electrodes AE1, AE2, and AE3 may be disposed on the second passivation layer PAS2 (e.g., disposed directly thereon in the third direction DR3). The different pixel electrodes AE1, AE2, and AE3 may each be disposed to overlap (e.g., in the third direction DR3) any one of the different openings OPA1, OPA2, and OPA3 of the pixel defining film PDL. The pixel electrodes AE1, AE2, and AE3 may be electrically connected to the drain electrode DE of the thin film transistor TFT through the first and second connection electrodes CNE1 and CNE2.

The light emitting layer EL may be disposed on the pixel electrodes AE1, AE2, and AE3. For example, in an embodiment the light emitting layer EL may be an organic light emitting layer made of an organic material. However, embodiments of the present disclosure are not necessarily limited thereto. In an embodiment in which the light emitting layer EL is an organic light emitting layer, the thin film transistor TFT applies a predetermined voltage to the pixel electrodes AE1, AE2, and AE3 of the light emitting element ED, and if the common electrode CE of the light emitting element ED receives a common voltage or a cathode voltage, the holes and electrons can move to the light emitting layer EL through the hole transporting layer and the electron transporting layer and combine to produce light to be emitted by the light emitting layer EL.

In an embodiment, the light emitting layers EL disposed on different pixel electrodes AE1, AE2, and AE3 may emit light of different colors. For example, in an embodiment the light emitting layer disposed on the first pixel electrode AE1 may emit red light of the first color, the light emitting layer disposed on the second pixel electrode AE2 may emit green light of the second color, and the light emitting layer disposed on the third pixel electrode AE3 may emit blue light of the third color. However, embodiments of the present disclosure are not necessarily limited thereto. For example, in an embodiment, the light emitting layer EL may be disposed as a single common layer on the different pixel electrodes AE1, AE2, and AE3 and the pixel defining film PDL, and the light emitting layer EL disposed on the different pixel electrodes AE1, AE2, and AE3 may emit light of the same color. In this embodiment, the display device 10 may further include a color adjustment layer disposed on the light emitting elements ED.

The common electrode CE may be disposed on the light emitting layer EL. For example, in an embodiment the common electrode CE may be made in the form of an electrode common to all of the pixels rather than specific to each of the pixels. The common electrode CE may be disposed on the light emitting layer EL in the first to third pixel electrodes AE1, AE2, and AE3, and may be disposed on the pixel defining film PDL in an area other than the first to third pixel electrodes AE1, AE2, and AE3.

The common electrode CE may receive the common voltage or a low potential voltage. When the pixel electrode AE receives a voltage corresponding to a data voltage and the common electrode CE receives the low potential voltage, a potential difference is formed between the pixel electrodes AE1, AE2, and AE3 and the common electrode CE, so that the light emitting layer EL may emit light.

The pixel defining film PDL may include the plurality of openings OPA1, OPA2, and OPA3, and may be disposed on a portion of the second passivation layer PAS2 and the pixel electrodes AE1, AE2, and AE3. The openings OPA1, OPA2, and OPA3 of the pixel defining film PDL may expose a portion of the pixel electrodes AE1, AE2, and AE3, respectively. As described above, each of the openings OPA1, OPA2, and OPA3 of the pixel defining film PDL may define the first to third emission areas LA1, LA2, and LA3, and the areas or sizes of the openings OPA1, OPA2, and OPA3 may be different from each other. The pixel defining film PDL may separate and insulate the pixel electrodes AE1, AE2, and AE3 of each of the plurality of light emitting elements ED.

The pixel defining film PDL may include a light absorbing material to prevent light reflection. For example, in an embodiment the pixel defining film PDL may include a polyimide (PI)-based binder and a pigment in which red, green, and blue colors are mixed. Alternatively, the pixel defining film PDL may include a cardo-based binder resin and a mixture of a lactam black pigment and a blue pigment. Alternatively, the pixel defining film PDL may include carbon black.

The encapsulation layer TFEL may be disposed on the common electrode CE to cover the plurality of light emitting elements ED. In an embodiment, the encapsulation layer TFEL may include at least one inorganic film to prevent oxygen or moisture from penetrating into the light emitting element layer EML. The encapsulation layer TFEL may include at least one organic film to protect the light emitting element layer EML from foreign matters such as dust.

In an embodiment, the encapsulation layer TFEL may include a first encapsulation layer TFE1, a second encapsulation layer TFE2, and a third encapsulation layer TFE3. The first encapsulation layer TFE1 and the third encapsulation layer TFE3 may be inorganic encapsulation layers, and the second encapsulation layer TFE2 disposed between the first encapsulation layer TFE1 and the third encapsulation layer TFE3 (e.g., in the third direction DR3) may be an organic encapsulation layer.

In an embodiment, each of the first encapsulation layer TFE1 and the third encapsulation layer TFE3 may include one or more inorganic insulating materials. The inorganic insulating material may include aluminum oxide, titanium oxide, tantalum oxide, hafnium oxide, zinc oxide, silicon oxide, silicon nitride, and/or silicon oxynitride.

In an embodiment, the second encapsulation layer TFE2 may include a polymer-based material. Examples of the polymer-based material may include acrylic resin, epoxy resin, polyimide, polyethylene and the like. For example, the second encapsulation layer TFE2 may include an acrylic resin, for example, polymethyl methacrylate, polyacrylic acid, or the like. In an embodiment, the second encapsulation layer TFE2 may be formed by curing a monomer or applying a polymer.

The touch sensing layer TSU may be disposed on the encapsulation layer TFEL (e.g., disposed directly thereon in the third direction DR3). In an embodiment, the touch sensing layer TSU may include a first touch insulating layer SIL1, a second touch insulating layer SIL2, the touch electrode TL, and a third touch insulating layer SIL3.

The first touch insulating layer SIL1 may be disposed on the encapsulation layer TFEL. For example, in an embodiment the first touch insulating layer SIL1 may directly contact the third encapsulation layer TFE3. The first touch insulating layer SIL1 may have an insulating and optical function. The first touch insulating layer SIL1 may include at least one inorganic film. However, embodiments of the present disclosure are not necessarily limited thereto. For example, in some embodiments the first touch insulating layer SIL1 may be omitted.

The second touch insulating layer SIL2 may cover the first touch insulating layer SILL. In an embodiment, a touch electrode of another layer may be further disposed on the first touch insulating layer SIL1, and the second touch insulating layer SIL2 may cover the touch electrode TL. The second touch insulating layer SIL2 may have an insulating and optical function. For example, in an embodiment the second touch insulating layer SIL2 may be an inorganic film containing at least one of a silicon nitride layer, a silicon oxynitride layer, a silicon oxide layer, a titanium oxide layer, or an aluminum oxide layer.

A portion of the touch electrode TL may be disposed on the second touch insulating layer SIL2. The touch electrode TL may not overlap the first to third pixel electrodes AE1, AE2, and AE3. In an embodiment, the touch electrode TL may be formed as a single layer containing molybdenum (Mo), titanium (Ti), copper (Cu), aluminum (Al), or indium tin oxide (ITO), or may be formed to have a stacked structure (Ti/Al/Ti) of aluminum and titanium, a stacked structure (ITO/Al/ITO) of aluminum and ITO, an Ag—Pd—Cu (APC) alloy, or a stacked structure (ITO/APC/ITO) of APC alloy and ITO.

The touch electrode TL of the touch sensing layer TSU may have a constant line width and may be disposed to overlap the first light blocking layer BM1, which will be described later. The first light blocking layer BM1 may have a width sufficient to completely cover the touch electrode TL, and a gap between an edge of the first light blocking layer BM1 and the touch electrode TL may be defined. In an embodiment, the line width of the touch electrode TL may be in a range of about 4 μm to about 6 m, and the gap between the touch electrode TL and the edge of the first light blocking layer BM1 may be in a range of about 5 μm to about 7 μm. In an embodiment, the touch electrode TL may be disposed such that its center is substantially aligned with the center of the first light blocking layer BM1, and the gap from both sides of the touch electrode TL to the edge of the first light blocking layer BM1 may be substantially constant.

The third touch insulating layer SIL3 may cover the touch electrode TL and the second touch insulating layer SIL2. The third touch insulating layer SIL3 may have an insulating and optical function. In an embodiment, the third touch insulating layer SIL3 may be made of a same material as the second touch insulating layer SIL2.

The first light blocking layer BM1 may be disposed on the third touch insulating layer SIL3 of the touch sensing layer TSU (e.g., disposed directly thereon in the third direction DR3). The first light blocking layer BM1 may be disposed to cover the conductive line of the touch electrode TL, while including the plurality of holes OPT1, OPT2, OPT3, OPT5, OPT6, and OPT7 that overlap the pixel electrodes AE1, AE2, and AE3. For example, the first hole OPT1 may be disposed to overlap the first emission area LA1 and the first pixel electrode AE1 of the first pixel PX1 (e.g., in the third direction DR3). The second hole OPT2 may be disposed to overlap the second emission area LA2 and the second pixel electrode AE2 of the first pixel PX1 (e.g., in the third direction DR3), and the third hole OPT3 may be disposed to overlap the third emission area LA3 and the third pixel electrode AE3 of the first pixel PX1 (e.g., in the third direction DR3). The fifth hole OPT5 may be disposed to overlap the first emission area LA1 and the first pixel electrode AE1 of the second pixel PX2 (e.g., in the third direction DR3). The sixth hole OPT6 may be disposed to overlap the second emission area LA2 and the second pixel electrode AE2 of the second pixel PX2 (e.g., in the third direction DR3), and the seventh hole OPT7 may be disposed to overlap the third emission area LA3 and the third pixel electrode AE3 of the second pixel PX2 (e.g., in the third direction DR3). In an embodiment, the area or size of each of the holes OPT1, OPT2, OPT3, OPT5, OPT6, and OPT7 may be greater than the area or size of the pixel electrodes AE1, AE2, and AE3 or the emission areas LA1, LA2, and LA3. In addition, the area or size of each of the holes OPT1, OPT2, and OPT3 may be formed to be larger than that of the corresponding opening of the pixel defining film PDL, and light emitted from the light emitting element ED may be visually recognized by the user not only from the front of the display device 10 but also from the side thereof.

The first light blocking layer BM1 may include a light absorbing material. For example, in an embodiment the first light blocking layer BM1 may include an inorganic black pigment or an organic black pigment. The inorganic black pigment may be carbon black, and the organic black pigment may include at least one of lactam black, perylene black, or aniline black. However, embodiments of the present disclosure are not necessarily limited thereto. The first light blocking layer BM1 may prevent visible light infiltration and color mixture between the holes OPT1, OPT2, and OPT3, which leads to the increased color reproducibility of the display device 10. In an embodiment, the first light blocking layer BM1 may have a thickness in a range of about 1 μm to about 3 μm. For example, in an embodiment the first light blocking layer BM1 may have a thickness of approximately 1.5 μm.

The color filters CF1, CF2, and CF3 of the color filter layer CFL may be disposed on (e.g., disposed directly thereon) the first light blocking layer BM1. The different color filters CF1, CF2, and CF3 may be disposed to correspond to the different emission areas LA1, LA2, and LA3 and the holes OPT1, OPT2, and OPT3 of the first light blocking layer BM1, respectively. For example, the first color filter CF1 may be disposed to correspond to the first emission area LA1, the second color filter CF2 may be disposed to correspond to the second emission area LA2, and the third color filter CF3 may be disposed to correspond to the third emission area LA3. The first color filter CF1 may be disposed in the first hole OPT1 of the first light blocking layer BM1, the second color filter CF2 may be disposed in the second hole OPT2 of the first light blocking layer BM1, and the third color filter CF3 may be disposed in the third hole OPT3 of the first light blocking layer BM1. In an embodiment, each of the color filters CF1, CF2, and CF3 may be disposed to have a larger area in the plan view than the hole OPT1, OPT2, OPT3 of the first light blocking layer BM1, and a portion thereof may be disposed directly on the first light blocking layer BM1.

The areas of the plurality of color filters CF1, CF2, and CF3 may vary depending on the sizes of the holes OPT1, OPT2, OPT3, OPT5, OPT6, and OPT7 of the first light blocking layer BM1. For example, in an embodiment the first color filter CF1 may have a larger area in the plan view than the second color filter CF2, but may have a smaller area in the plan view than the third color filter CF3. In some embodiments, the first color filter CF1 disposed in the first pixel PX1 may have the same area in the plan view as the first color filter CF1 disposed in the second pixel PX2. However, embodiments of the present disclosure are not necessarily limited thereto. In some embodiments, the first color filter CF1 disposed in the first pixel PX1 may have a larger area in the plan view than the first color filter CF1 disposed in the second pixel PX2.

The passivation layers PSV1 and PSV2 may be disposed on the first light blocking layer BM1 and the color filter layer CFL. In an embodiment, the passivation layers PSV1 and PSV2 may be disposed over the entire display area DA to flatten the top surface of the display panel 100. The passivation layers PSV1 and PSV2 may include a first passivation layer PSV1 disposed on (e.g., disposed directly thereon) the color filter layer CFL and the first light blocking layer BM1, and a second passivation layer PSV2 disposed on (e.g., disposed directly thereon) the first passivation layer PSV1. The passivation layers PSV1 and PSV2 may be formed as a plurality of layers and flatten the stepped portion caused by the color filter layer CFL and the first light blocking layer BM1.

In an embodiment, the passivation layers PSV1 and PSV2 may be a colorless light transmissive layer that does not have a color in a visible light band. For example, in an embodiment the passivation layers PSV1 and PSV2 may include a colorless light transmissive organic material such as an acrylic resin.

The second light blocking layer BM2 may be disposed on the passivation layers PSV1 and PSV2. For example, the second light blocking layer BM2 may directly contact the second passivation layer PSV2. The second light blocking layer BM2 may not be disposed in the first type pixel (or the first pixel PX1), but may be disposed only in the second type pixel (or the second pixel PX2). The second light blocking layer BM2 may be disposed to correspond to the peripheries of the emission areas LA1, LA2, and LA3 of the second type pixel. The second light blocking layer BM2 may be disposed to at least partially overlap each of the emission areas LA1, LA2, and LA3 of the second type pixel. For example, the second light blocking layer BM2 may be disposed to partially overlap each of the first emission area LA1, the second emission area LA2, and the third emission area LA3 of the second pixel PX2 and the fourth pixel PX4. As shown in FIG. 9, the second light blocking layer BM2 may be disposed to overlap the right side of each emission area LA1, LA2, and LA3 of the second pixel PX2. In addition, as shown in FIG. 10, the second light blocking layer BM2 may be disposed to overlap the left side of each emission area LA1, LA2, and LA3 of the fourth pixel PX4.

In addition, the second light blocking layer BM2 may be disposed to at least partially overlap the holes OPT5, OPT6, and OPT7 of the first light blocking layer BM1 of the second type pixel. For example, the second light blocking layer BM2 may be disposed to partially overlap each of the holes OPT5, OPT6, and OPT7 of the second pixel PX2 and the fourth pixel PX4.

When the display device 10 is viewed from one side, the light emitted from the second type pixel may be obscured by the second light blocking layer BM2 although the light passes through the holes OPT5, OPT6, and OPT7 of the first light blocking layer BM1. For example, when the display device 10 is viewed from the left side, the light emitted from the fourth pixel PX4 may be blocked by the second light blocking layer BM2 even if the light passes through the holes OPT5, OPT6, and OPT7 of the first light blocking layer BM1. Further, when the display device 10 is viewed from the right side, the light emitted from the second pixel PX2 may be blocked by the second light blocking layer BM2 even if the light passes through the holes OPT5, OPT6, and OPT7 of the first light blocking layer BM1. In other words, the display device 10 may allow only the second pixel PX2 and the fourth pixel PX4 or the second type pixel in which the second light blocking layer BM2 is disposed to emit light in the second emission mode, thereby controlling visibility at a specific viewing angle and providing a privacy protection mode to the user.

The second light blocking layer BM2 may include a light absorbing material. For example, the second light blocking layer BM2 may include an inorganic black pigment or an organic black pigment. The inorganic black pigment may be carbon black, and the organic black pigment may include at least one of lactam black, perylene black, or aniline black, but they are not limited thereto. In an embodiment, the second light blocking layer BM2 may have a thickness of 1 μm to 3 μm, or about 1.5 μm.

The overcoat layer OC may be disposed on the second light blocking layer BM2 and the passivation layers PSV1 and PSV2. The overcoat layer OC may be disposed over the entire display area DA to flatten the top surface of the display panel 100. The overcoat layer OC may be a colorless light transmissive layer that does not have a color in a visible light band. For example, in an embodiment the overcoat layer OC may include a colorless light transmissive organic material such as an acrylic resin.

Hereinafter, the second light blocking layer BM2 and the emission areas LA1, LA2, and LA3 of the display device 10 will be described in more detail with reference to other drawings.

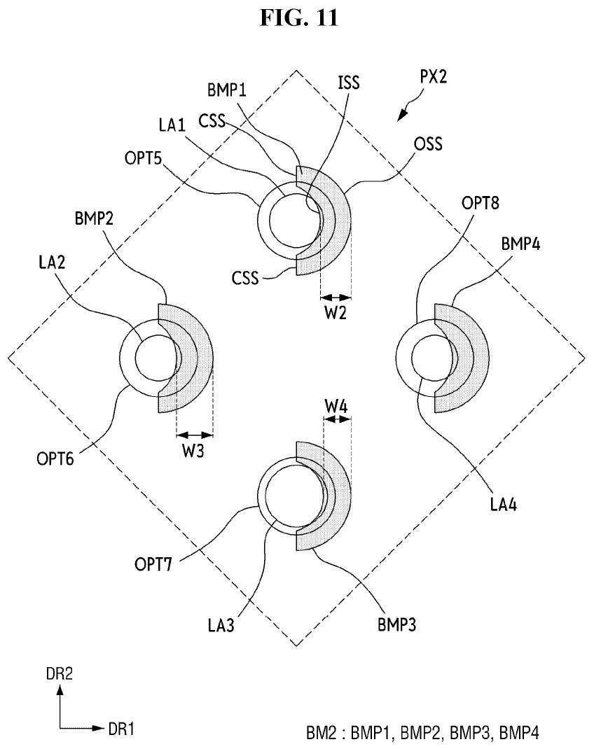

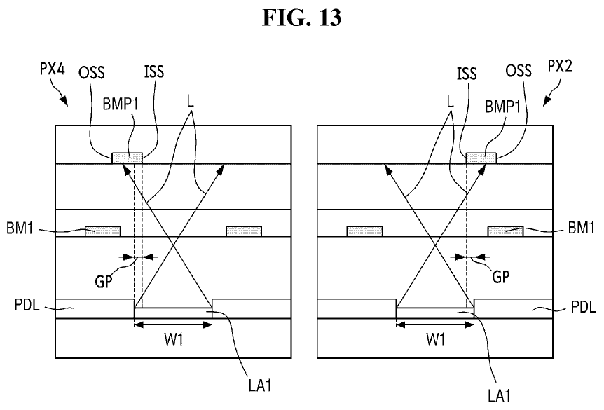

FIG. 11 is a diagram illustrating the relative arrangement of an emission area and a second light blocking layer disposed in the second pixel of the display device according to an embodiment. FIG. 12 is a diagram illustrating the relative arrangement of an emission area and a second light blocking layer disposed in the fourth pixel of the display device according to an embodiment. FIG. 13 is an diagram illustrating an emission direction of light emitted from an emission area of a display device and a relative arrangement of a second light blocking layer. FIG. 13 shows the first emission area LA1 of the second pixel PX2 and the first emission area LA1 of the fourth pixel PX4.

Referring to FIGS. 11 to 13, the second light blocking layer BM2 may include the light blocking patterns BMP1, BMP2, BMP3, and BMP4 that respectively correspond to the emission areas LA1, LA2, LA3, and LA4 in the second pixel PX2 and the fourth pixel PX4 and surround one side or the other side of the emission areas LA1, LA2, LA3, and LA4 in the plan view. For example, the second light blocking layer BM2 may include the first light blocking pattern BMP1 surrounding the first emission area LA1, the second light blocking pattern BMP2 surrounding the second emission area LA2, the third light blocking pattern BMP3 surrounding the third emission area LA3, and the fourth light blocking pattern BMP4 surrounding the fourth emission area LA4. Similarly to the number and layout of the emission areas LA1, LA2, LA3, and LA4 included in one pixel PX, in an embodiment one second pixel PX2 may include four light blocking patterns BMP1, BMP2, BMP3, and BMP4 that may be spaced apart diagonally from each other. In addition, one fourth pixel PX4 may include four light blocking patterns BMP1, BMP2, BMP3, and BMP4 that may be spaced apart diagonally from each other. However, embodiments of the present disclosure are not necessarily limited thereto.

In an embodiment, the plurality of light blocking patterns BMP1, BMP2, BMP3, and BMP4 of the second light blocking layer BM2 may overlap the emission areas LA1, LA2, LA3, and LA4 and the holes OPT5, OPT6, OPT7, and OPT8 of the first light blocking layer BM1, and may have a semi-ring shape (e.g., in a plan view). In an embodiment, the semi-ring shape may be a right opened or left opened shape. For example, the light blocking patterns BMP1, BMP2, BMP3, and BMP4 disposed in the second pixel PX2 may have a semi-ring shape that is opened in the opposite direction to the first direction DR1, such as the left direction. The light blocking patterns BMP1, BMP2, BMP3, and BMP4 disposed in the fourth pixel PX4 may have a semi-ring shape that is opened in the first direction DR1, such as the right direction.

In an embodiment, the light blocking patterns BMP1, BMP2, BMP3, and BMP4 disposed in the second pixel PX2, and the light blocking patterns BMP1, BMP2, BMP3, and BMP4 disposed in the fourth pixel PX4 may be symmetrical to each other in the second direction DR2 that crosses the first pixel PX1 and the third pixel PX3. For example, the opening direction of the semi-ring shape of the light blocking patterns BMP1, BMP2, BMP3, and BMP4 disposed in the second pixel PX2 may face the opening direction of the semi-ring shape of the light blocking patterns BMP1, BMP2, BMP3, and BMP4 disposed in the fourth pixel PX4. In an embodiment, the opening direction of the semi-ring shape of the light blocking patterns BMP1, BMP2, BMP3, and BMP4 disposed in the second pixel PX2 may be the opposite direction to the first direction DR1, such as the left direction. The opening direction of the semi-ring shape of the light blocking patterns BMP1, BMP2, BMP3, and BMP4 disposed in the fourth pixel PX4 may be the first direction DR1, such as the right direction.

In an embodiment, each of the light blocking patterns BMP1, BMP2, BMP3, and BMP4 disposed in the second pixel PX2 and the fourth pixel PX4 may include a curved outer side surface OSS and a curved inner side surface ISS (e.g., in a plan view), and a connection surface CSS that connects the outer side surface OSS to the inner side surface ISS. For example, in an embodiment the light blocking patterns BMP1, BMP2, BMP3, and BMP4 disposed in the second pixel PX2 may include the outer side surface OSS that is convex in the first direction DR1, the inner side surface ISS that is concave in the first direction DR1, and the connection surfaces CSS that extend in the second direction DR2 and connect the outer side surface OSS to the inner side surface ISS. In an embodiment, the light blocking patterns BMP1, BMP2, BMP3, and BMP4 disposed in the fourth pixel PX4 may include the outer side surface OSS that is convex in the opposite direction to the first direction DR1, the inner side surface ISS that is concave in the opposite direction to the first direction DR1, and the connection surfaces CSS that extend in the second direction DR2 and connect the outer side surface OSS to the inner side surface ISS.

In the light blocking patterns BMP1, BMP2, BMP3, and BMP4 disposed in the second pixel PX2, the inner side surfaces ISS thereof may overlap (e.g., in the third direction DR3) the emission areas LA1, LA2, LA3, and LA4, and the outer side surfaces OSS thereof may overlap (e.g., in the third direction DR3) the first light blocking layer BM1. In the light blocking patterns BMP1, BMP2, BMP3, and BMP4 disposed in the second pixel PX2, the inner side surfaces ISS thereof may not overlap the first light blocking layer BM1 (e.g., in the third direction DR3). In addition, in the light blocking patterns BMP1, BMP2, BMP3, and BMP4 disposed in the fourth pixel PX4, the inner side surfaces ISS thereof may overlap (e.g., in the third direction DR3) the emission areas LA1, LA2, LA3, and LA4 and the outer side surfaces OSS thereof may overlap (e.g., in the third direction DR3) the first light blocking layer BM1. In the light blocking patterns BMP1, BMP2, BMP3, and BMP4 disposed in the fourth pixel PX4, the inner side surfaces ISS thereof may not overlap the first light blocking layer BM1 (e.g., in the third direction DR3).

The light blocking patterns BMP1, BMP2, BMP3, and BMP4 disposed in the second pixel PX2 and the fourth pixel PX4 may overlap (e.g., in the third direction DR3) the emission areas LA1, LA2, LA3, and LA4, respectively. For example, the light blocking pattern BMP1, BMP2, BMP3, BMP4 disposed in the second pixel PX2 may overlap (e.g., in the third direction DR3) at least a portion of the emission area LA1, LA2, LA3, LA4. The light blocking pattern BMP1, BMP2, BMP3, BMP4 disposed in the fourth pixel PX4 may overlap (e.g., in the third direction DR3) at least a portion of the emission area LA1, LA2, LA3, LA4.

In an embodiment, the inner side surface ISS of the light blocking pattern BMP1, BMP2, BMP3, BMP4 disposed in the second pixel PX2 and the fourth pixel PX4 and the side surface of the emission area LA1, LA2, LA3, LA4 may be located to be spaced apart from each other at a predetermined gap GP in the plan view. In this embodiment, the side surface of the emission area LA1, LA2, LA3, LA4 may be the side surface of the pixel defining film PDL that meets (e.g., is co-planar therewith in the third direction DR3) the top surfaces of the pixel electrodes AE1, AE2, and AE3 (see FIG. 10). In an embodiment, the gap GP between the inner side surface ISS of the light blocking pattern BMP1, BMP2, BMP3, BMP4 and the side surface of the emission area LA1, LA2, LA3, LA4 in the second pixel PX2 may be in a range from about 1% to about 10% of a diameter W1 of the emission area LA1, LA2, LA3, LA4. Similarly, in the fourth pixel PX4, the gap GP between the inner side surface ISS of the light blocking pattern BMP1, BMP2, BMP3, BMP4 and the side surface of the emission area LA1, LA2, LA3, LA4 may be in a range from about 1% to about 10% of the diameter W1 of the emission area LA1, LA2, LA3, LA4. In this embodiment, if the gap GP between the inner side surface ISS of the light blocking pattern BMP1, BMP2, BMP3, BMP4 and the side surface of the emission area LA1, LA2, LA3, LA4 is greater than or equal to about 1% of the diameter W1 of the emission area LA1, LA2, LA3, LA4, light is blocked from being emitted towards one side where the light blocking patterns BMP1, BMP2, BMP3, and BMP4 are disposed, thereby providing a privacy protection mode to the user. In addition, if the gap GP between the inner side surface ISS of the light blocking pattern BMP1, BMP2, BMP3, BMP4 and the side surface of the emission area LA1, LA2, LA3, LA4 is less than or equal to about 10% of the diameter W1 of the emission area LA1, LA2, LA3, LA4, it is possible to prevent the amount of light emitted toward the front, that is, the luminance, from being decreased.

As shown in FIG. 13, the light blocking patterns BMP1, BMP2, BMP3, and BMP4 of the second pixel PX2 may block light L emitted to the right side (e.g., in the first direction DR1) in each of the emission areas LA1, LA2, LA3, and LA4. Further, the light blocking patterns BMP1, BMP2, BMP3, and BMP4 of the fourth pixel PX4 may block light L emitted to the left side, (e.g., in the opposite direction to the first direction DR1) in each of the emission areas LA1, LA2, LA3, and LA4. Accordingly, the display device 10 is capable of providing a privacy protection mode to the user in the second emission mode because the screen may not be visually recognized by the user looking at a specific viewing angle or from the side (e.g., the left or the right side).

In addition, light may be emitted towards the front and left side (e.g., in the opposite direction to the first direction DR1) in each of the emission areas LA1, LA2, LA3, and LA4 of the second pixel PX2, and light may be emitted toward the front and right side (e.g., in the first direction DR1) in each of the emission areas LA1, LA2, LA3, and LA4 of the fourth pixel PX4. For example, the amount of light emitted in the front direction may be increased in the second pixel PX2 and the fourth pixel PX4. The display device 10 is capable of increasing the front luminance by increasing the amount of light emitted towards the front in the first emission mode.

According to an embodiment, the sizes or areas of the light blocking patterns BMP1, BMP2, BMP3, and BMP4 disposed in the second pixel PX2 and the fourth pixel PX4 may be different from each other. For example, in the second pixel PX2, a width W2 of the first light blocking pattern BMP1 may be less than a width W3 of the second light blocking pattern BMP2, and may be greater than a width W4 of the third light blocking pattern BMP3. In this embodiment, the width of the light blocking pattern may be a width that is measured along a line that extends from the center point of the emission area in the first direction DR1. The widths of the light blocking patterns BMP1, BMP2, BMP3, and BMP4 may be related to the diameters of the emission areas LA1, LA2, LA3, and LA4. In an embodiment, the display device 10 may have a magnitude relationship between the widths of the light blocking patterns BMP1, BMP2, BMP3, and BMP4, which is opposite to the magnitude relationship between the diameters of the emission areas LA1, LA2, LA3, and LA4. For example, in an embodiment the diameter of the third emission area LA3 is greater than the diameters of the first emission area LA1 and the second emission area LA2, but the width W4 of the third light blocking pattern BMP3 may be less than the width W2 and width W3 of the first light blocking pattern BMP1 and the second light blocking pattern BMP2. The diameter of the second emission area LA2 is less than that of the first emission area LA1, but the width W3 of the second light blocking pattern BMP2 may be greater than the width W2 of the first light blocking pattern BMP1. In an embodiment, although the diameters of the emission areas LA1, LA2, LA3, and LA4 decrease in the order of the third emission area LA3, the first emission area LA1, and the second emission area LA2 (the same as the fourth emission area LA4), the widths of the light blocking patterns BMP1, BMP2, BMP3, and BMP4 may increase in the order of the third light blocking pattern BMP3, the first light blocking pattern BMP1, and the second light blocking pattern BMP2 (the same as the fourth light blocking pattern BMP4). However, embodiments of the present disclosure are not necessarily limited thereto. For example, if the diameters of the emission areas LA1, LA2, LA3, and LA4 are the same, the widths, areas, or sizes of the light blocking patterns BMP1, BMP2, BMP3, and BMP4 may also be the same.

The display device 10 according to an embodiment may include the first light blocking layer BM1 and the second light blocking layer BM2 to control the visibility of the screen at a specific viewing angle depending on the emission mode of the display device 10. In the display device 10, the shapes, layout, and the like of the emission areas LA1, LA2, LA3, and LA4 and the light blocking patterns BMP1, BMP2, BMP3, and BMP4 of the first light blocking layer BM1 and the second light blocking layer BM2 are designed, so that the visibility at a specific viewing angle may be blocked to provide a private mode to the user, and the front luminance may be increased.

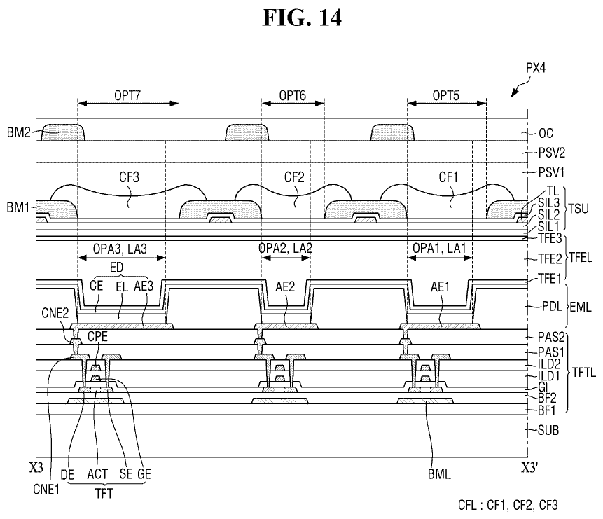

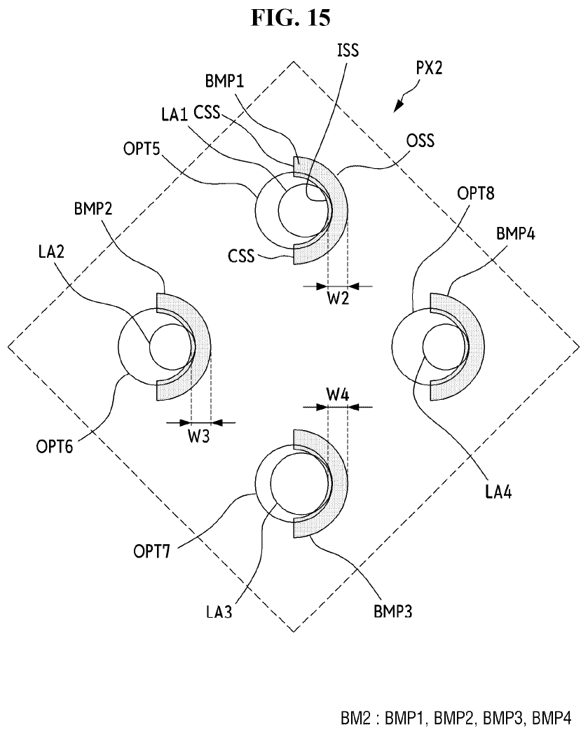

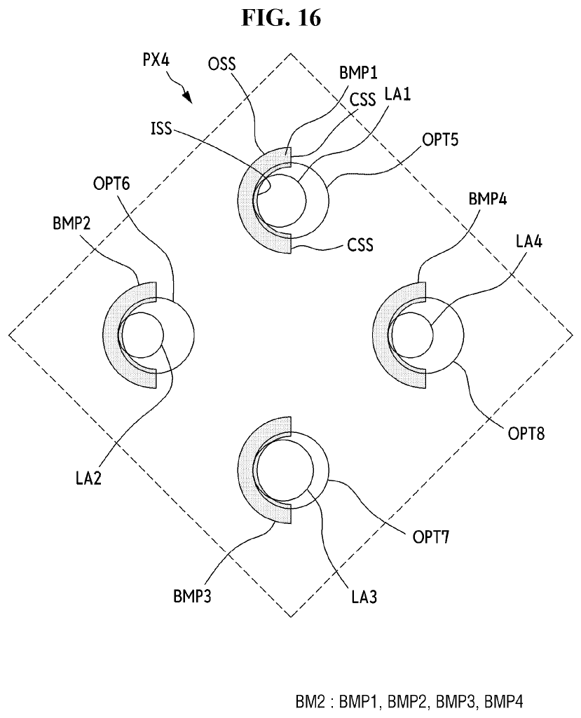

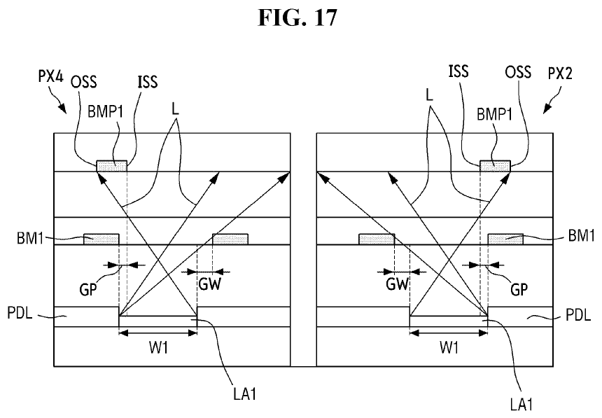

FIG. 14 is a cross-sectional view showing a fourth pixel of a display device according to an embodiment. FIG. 15 is a diagram illustrating the relative arrangement of an emission area and a second light blocking layer disposed in the second pixel of the display device according to an embodiment. FIG. 16 is a diagram illustrating the relative arrangement of an emission area and a second light blocking layer disposed in the fourth pixel of the display device according to an embodiment. FIG. 17 is an diagram illustrating an emission direction of light emitted from an emission area of a display device and a relative arrangement of a second light blocking layer. FIG. 17 shows the first emission area LA1 of the second pixel PX2 and the first emission area LA1 of the fourth pixel PX4.

Referring to FIGS. 14 to 17, the display device 10 according to an embodiment is different from the aforementioned embodiment in that the side surfaces of the emission areas LA1, LA2, LA3, and LA4 of the second pixel PX2 and the fourth pixel PX4 are aligned (e.g., along the third direction DR3) and coincide with the side surfaces of the holes OPT5, OPT6, OPT7, and OPT8 of the first light blocking layer BM1, respectively, and the sizes, areas, or widths of the light blocking patterns BMP1, BMP2, BMP3, and BMP4 of the second light blocking layer BM2 are the same as each other.

According to an embodiment, the side surfaces of the emission areas LA1, LA2, LA3, and LA4 of the second pixel PX2 and the fourth pixel PX4 may be aligned and coincide with the side surfaces of the holes OPT5, OPT6, OPT7, and OPT8 of the first light blocking layer BM1, respectively. For example, in an embodiment, in the fourth pixel PX4, one side surface (e.g., a first side surface) of the first emission area LA1 may be aligned with one side surface (e.g., a first side surface) of the fifth hole OPT5 of the first light blocking layer BM1, one side surface (e.g., a first side surface) of the second emission area LA2 may be aligned with one side surface (e.g., a first side surface) of the sixth hole OPT6 thereof, one side surface (e.g., a first side surface) of the third emission area LA3 may be aligned with one side surface (e.g., a first side surface) of the seventh hole OPT7 thereof, and one side surface (e.g., a first side surface) of the fourth emission area LA4 may be aligned with one side surface (e.g., a first side surface) of the eighth hole OPT8 thereof. Further, in the second pixel PX2, one side surface (e.g., a first side surface) of the first emission area LA1 may be aligned with one side surface (e.g., a first side surface) of the fifth hole OPT5 of the first light blocking layer BM1, one side surface (e.g., a first side surface) of the second emission area LA2 may be aligned with one side surface (e.g., a first side surface) of the sixth hole OPT6 thereof, one side surface (e.g., a first side surface) of the third emission area LA3 may be aligned with one side surface (e.g., a first side surface) of the seventh hole OPT7 thereof, and one side surface (e.g., a first side surface) of the fourth emission area LA4 may be aligned with one side surface (e.g., a first side surface) of the eighth hole OPT8 thereof.

In an embodiment, the right side surface of each emission area LA1, LA2, LA3, LA4 of the second pixel PX2 (e.g., the surface disposed on the rightmost side of the circle in the plan view) may be aligned with the right side surface of the hole OPT5, OPT6, OPT7, OPT8 of the first light blocking layer BM1 (e.g., the surface disposed on the rightmost side of the circle in the plan view). The left side surface of each emission area LA1, LA2, LA3, LA4 of the fourth pixel PX4 (e.g., the surface disposed on the leftmost side of the circle in the plan view) may be aligned with the left side surface of the hole OPT5, OPT6, OPT7, OPT8 of the first light blocking layer BM1 (e.g., the surface disposed on the leftmost side of the circle in the plan view).

As one side surface (e.g., a first side surface) of each emission area LA1, LA2, LA3, LA4 of the second pixel PX2 and the fourth pixel PX4 is aligned with one side surface (e.g., a first side surface) of the hole OPT5, OPT6, OPT7, OPT8 of the first light blocking layer BM1, the other side surface (e.g., an opposite second side surface) of each emission area LA1, LA2, LA3, LA4 may be disposed to be spaced apart from the other side surface (e.g., an opposite second side surface) of the hole OPT5, OPT6, OPT7, OPT8 of the first light blocking layer BM1. For example, the left side surface of each emission area LA1, LA2, LA3, LA4 of the second pixel PX2 (e.g., the surface disposed on the leftmost side of the circle in the plan view) may be spaced apart from the left side surface of hole OPT5, OPT6, OPT7, OPT8 of the first light blocking layer BM1 (e.g., the surface disposed on the leftmost side of the circle in the plan view). The right side surface of each emission area LA1, LA2, LA3, LA4 of the fourth pixel PX4 (e.g., the surface disposed on the rightmost side of the circle in the plan view) may be spaced apart from the right side surface of hole OPT5, OPT6, OPT7, OPT8 of the first light blocking layer BM1 (e.g., the surface disposed on the rightmost side of the circle in the plan view).

In an embodiment, in the second pixel PX2, a gap GW between the other side surface (e.g., the leftmost side surface) of each emission area LA1, LA2, LA3, LA4 and the other side surface (e.g., the leftmost side surface) of the hole OPT5, OPT6, OPT7, OPT8 of the first light blocking layer BM1 may be in a range of about 2% to about 20% of the diameter W1 of the emission area LA1, LA2, LA3, LA4. Similarly, in the fourth pixel PX4, the gap GW between the other side surface (e.g., the rightmost side surface) of each emission area LA1, LA2, LA3, LA4 and the other side surface (e.g., the rightmost side surface) of the hole OPT5, OPT6, OPT7, OPT8 of the first light blocking layer BM1 may be in a range of about 2% to about 20% of the diameter W1 of the emission area LA1, LA2, LA3, LA4. In this embodiment, if the gap GW between the other side surface of each emission area LA1, LA2, LA3, LA4 and the other side surface of the hole OPT5, OPT6, OPT7, OPT8 of the first light blocking layer BM1 is greater than or equal to about 2% of the diameter W1 of the emission area LA1, LA2, LA3, LA4, the front luminance may be increased by increasing the amount of light emitted to the area between the second pixel PX2 and the fourth pixel PX4, such as the front area, in the first emission mode. In addition, if the gap GW between the other side surface of each emission area LA1, LA2, LA3, LA4 and the other side surface of the hole OPT5, OPT6, OPT7, OPT8 of the first light blocking layer BM1 is less than or equal to about 20% of the diameter W1 of the emission area LA1, LA2, LA3, LA4, in the second emission mode, light emitted from the second pixel PX2 and the fourth pixel PX4 towards the front can be prevented from being blocked by the first light blocking layer BM1 or the second light blocking layer BM2.

In an embodiment, the plurality of light blocking patterns BMP1, BMP2, BMP3, and BMP4 of the second light blocking layer BM2 may overlap (e.g., in the third direction DR3) the emission areas LA1, LA2, LA3, and LA4 and the holes OPT5, OPT6, OPT7, and OPT8 of the first light blocking layer BM1, and may have a semi-ring shape. Each of the light blocking patterns BMP1, BMP2, BMP3, and BMP4 disposed in the second pixel PX2 and the fourth pixel PX4 may include a curved outer side surface OSS and a curved inner side surface ISS, and a connection surface CSS that connects the outer side surface OSS to the inner side surface ISS.

In the light blocking patterns BMP1, BMP2, BMP3, and BMP4 disposed in the second pixel PX2, the inner side surfaces ISS thereof may overlap the emission areas LA1, LA2, LA3, and LA4, and the outer side surfaces OSS thereof may overlap the first light blocking layer BM1. In the light blocking patterns BMP1, BMP2, BMP3, and BMP4 disposed in the second pixel PX2, the inner side surfaces ISS thereof may not overlap the first light blocking layer BM1. In addition, in the light blocking patterns BMP1, BMP2, BMP3, and BMP4 disposed in the fourth pixel PX4, the inner side surfaces ISS thereof may overlap the emission areas LA1, LA2, LA3, and LA4 and the outer side surfaces OSS thereof may overlap the first light blocking layer BM1. In the light blocking patterns BMP1, BMP2, BMP3, and BMP4 disposed in the fourth pixel PX4, the inner side surfaces ISS thereof may not overlap the first light blocking layer BM1.

The light blocking patterns BMP1, BMP2, BMP3, and BMP4 disposed in the second pixel PX2 and the fourth pixel PX4 may overlap the emission areas LA1, LA2, LA3, and LA4, respectively. For example, the light blocking pattern BMP1, BMP2, BMP3, BMP4 disposed in the second pixel PX2 may overlap at least a portion of the emission area LA1, LA2, LA3, LA4. The light blocking pattern BMP1, BMP2, BMP3, BMP4 disposed in the fourth pixel PX4 may overlap at least a portion of the emission area LA1, LA2, LA3, LA4.

In an embodiment, in the second pixel PX2, the gap GP between the inner side surface ISS of the light blocking pattern BMP1, BMP2, BMP3, BMP4 and the side surface of the emission area LA1, LA2, LA3, LA4 may be in a range of about 1% to about 10% of the diameter W1 of the emission area LA1, LA2, LA3, LA4. Similarly, in the fourth pixel PX4, the gap GP between the inner side surface ISS of the light blocking pattern BMP1, BMP2, BMP3, BMP4 and the side surface of the emission area LA1, LA2, LA3, LA4 may be in a range of about 1% to about 10% of the diameter W1 of the emission area LA1, LA2, LA3, LA4.

As shown in FIG. 17, the light blocking patterns BMP1, BMP2, BMP3, and BMP4 of the second pixel PX2 may block light L emitted to the right side (e.g., in the first direction DR1) in each of the emission areas LA1, LA2, LA3, and LA4. Further, the light blocking patterns BMP1, BMP2, BMP3, and BMP4 of the fourth pixel PX4 may block light L emitted to the left side, (e.g., in the opposite direction to the first direction DR1) in each of the emission areas LA1, LA2, LA3, and LA4. Accordingly, the display device 10 is capable of providing a privacy protection mode to the user in the second emission mode because the screen may not be visually recognized by the user looking at a specific viewing angle or from the side (e.g., the left side or the right side).

In addition, light may be emitted towards the front and left side (e.g., in the opposite direction to the first direction DR1) in each of the emission areas LA1, LA2, LA3, and LA4 of the second pixel PX2, and light may be emitted towards the front and right side (e.g., in the first direction DR1) in each of the emission areas LA1, LA2, LA3, and LA4 of the fourth pixel PX4. For example, the amount of light emitted in the front direction may be increased in the second pixel PX2 and the fourth pixel PX4. The display device 10 is capable of increasing the front luminance by increasing the amount of light emitted towards the front in the first emission mode.

According to an embodiment, the sizes or areas of the light blocking patterns BMP1, BMP2, BMP3, and BMP4 disposed in the second pixel PX2 and the fourth pixel PX4 may be the same as each other. For example, in the second pixel PX2, a width W2 of the first light blocking pattern BMP1 may be the same as a width W3 of the second light blocking pattern BMP2 and a width W4 of the third light blocking pattern BMP3.

The display device 10 according to an embodiment may include the first light blocking layer BM1 and the second light blocking layer BM2 to control the visibility of the screen at a specific viewing angle depending on the emission mode of the display device 10. In the display device 10, the shapes, layout, and the like of the emission areas LA1, LA2, LA3, and LA4 and the light blocking patterns BMP1, BMP2, BMP3, and BMP4 of the first light blocking layer BM1 and the second light blocking layer BM2 are designed, so that the visibility at a specific viewing angle may be blocked to provide a private mode to the user, and the front luminance may be increased.

In concluding the detailed description, those skilled in the art will appreciate that many variations and modifications can be made to the described embodiments without substantially departing from the principles of the present disclosure. Therefore, the described embodiments of the present disclosure are used in a generic and descriptive sense only and not for purposes of limitation.

What is claimed is:

1. A display device comprising:
a display area including a plurality of pixels comprising a plurality of emission areas spaced apart from each other;
a first light blocking layer disposed on the display area, the first light blocking layer comprising a plurality of holes overlapping the plurality of emission areas;
a plurality of color filters disposed on the first light blocking layer, the plurality of color filters is arranged to respectively correspond to the plurality of holes; and
a second light blocking layer disposed on the plurality of color filters, the second light blocking layer is arranged to correspond to the plurality of emission areas of a first portion of the plurality of pixels,
wherein the second light blocking layer is disposed to surround the plurality of emission areas of the first portion of the plurality of pixels in a plan view, the second light blocking layer comprising a plurality of light blocking patterns overlapping the plurality of emission areas of the first portion of the plurality of pixels.

2. The display device of claim 1, wherein:
the plurality of pixels comprise a first pixel, a second pixel, a third pixel, and a fourth pixel; and
the first portion of the plurality of pixels includes the second pixel and the fourth pixel and does not include the first pixel and the third pixel.

3. The display device of claim 2, wherein:
the second pixel and the fourth pixel are spaced apart in a first direction, the first pixel and the third pixel are spaced apart in a second direction crossing the first direction, and planar shapes of the plurality of light blocking patterns are symmetrical to each other with respect to an axis extending in the second direction between the second pixel and the fourth pixel.

4. The display device of claim 2, wherein:
the plurality of emission areas of the first portion of the plurality of pixels comprises at least a first emission area;
the plurality of light blocking patterns comprises at least a first light blocking pattern overlapping the first emission area; and
a gap in the plan view between a side surface of the first emission area and an inner side surface of the first light blocking pattern is in a range of about 1% to about 10% of a diameter of the first emission area.

5. The display device of claim 4, wherein:
the inner side surface of the first light blocking pattern overlaps the first emission area and does not overlap the first light blocking layer; and
an outer side surface of the first light blocking pattern overlaps the first light blocking layer and does not overlap the first emission area.

6. The display device of claim 4, wherein:
the plurality of emission areas of the first portion of the plurality of pixels comprises a second emission area and a third emission area, the plurality of light blocking patterns comprises a second light blocking pattern overlapping the second emission area and a third light blocking pattern overlapping the third emission area;
a width of the second light blocking pattern is greater than a width of the first light blocking pattern and a width of the third light blocking pattern; and
the width of the first light blocking pattern is greater than the width of the third light blocking pattern.

7. The display device of claim 6, wherein:
a diameter of the third emission area is greater than the diameter of the first emission area and a diameter of the second emission area; and
the diameter of the first emission area is greater than the diameter of the second emission area.

8. The display device of claim 4, wherein the plurality of holes comprise at least a first hole overlapping the first emission area, and first side surfaces of the first emission area and the first hole adjacent to each other are aligned and coincide with each other in a thickness direction.

9. The display device of claim 8, wherein a gap in the plan view between a second side surface of the first emission area opposite to the first side surface of the first emission area and a second side surface of the first hole opposite to the first side surface of the first hole is in a range of about 2% to about 20% of the diameter of the first emission area.

10. The display device of claim 8, wherein each of the plurality of light blocking patterns has a same width as each other.

11. The display device of claim 2, wherein:
the plurality of light blocking patterns has a semi-ring shape that is opened in one direction in the plan view; and
an opening direction of the plurality of light blocking patterns disposed in the second pixel and an opening direction of the plurality of light blocking patterns disposed in the fourth pixel face each other.

12. The display device of claim 1, wherein the plurality of light blocking patterns overlaps the plurality of holes overlapping the plurality of emission areas of the first portion of the plurality of pixels corresponding thereto, respectively.

13. The display device of claim 1, further comprising:
a pixel electrode disposed on the display area;
a pixel defining film covering an edge of the pixel electrode;
a light emitting layer disposed on the pixel electrode; and
a common electrode disposed on the light emitting layer,
wherein each of the plurality of emission areas is defined by an opening of the pixel defining film overlapping the pixel electrode.

14. A display device comprising:
a substrate;
a light emitting element layer disposed on the substrate, the light emitting element layer comprising a plurality of emission areas;
an encapsulation layer disposed on the light emitting element layer;
a first light blocking layer disposed on the encapsulation layer, the first light blocking layer comprising a plurality of holes respectively disposed to correspond to the plurality of emission areas;
a color filter layer disposed on the encapsulation layer, the color filter layer comprising a plurality of color filters disposed in the plurality of holes; and
a light blocking member layer disposed on the color filter layer, the light blocking member layer comprising a second light blocking layer overlapping a first portion of the plurality of emission areas,
wherein the second light blocking layer overlapping the first portion of the plurality of emission areas overlaps the first light blocking layer and the plurality of holes.

15. The display device of claim 14, wherein the plurality of emission areas includes a first pixel and a second pixel, the second light blocking layer comprises a plurality of light blocking patterns, and the plurality of light blocking patterns overlaps the second pixel and does not overlap the first pixel.

16. The display device of claim 15, wherein:
the plurality of emission areas disposed to overlap the second pixel comprises at least a first emission area;
the plurality of light blocking patterns comprises at least a first light blocking pattern overlapping the first emission area; and
a gap in a plan view between a side surface of the first emission area and an inner side surface of the first light blocking pattern is in a range of about 1% to about 10% of a diameter of the first emission area.

17. The display device of claim 16, wherein:
the plurality of holes comprises at least a first hole overlapping the first emission area, and first side surfaces of the first emission area and the first hole adjacent to each other are aligned and coincide with each other in a thickness direction.

18. The display device of claim 17, wherein a gap in the plan view between a second side surface of the first emission area opposite to the first side surface of the first emission area and a second side surface of the first hole opposite to the first side surface of the first hole is in a range of about 2% to about 20% of a diameter of the first emission area.

19. The display device of claim 15, wherein:
the plurality of emission areas includes a third pixel spaced apart from the second pixel in a first direction; the plurality of light blocking patterns overlap the third pixel; and
the plurality of light blocking patterns have a semi-ring shape that is opened in one direction.

20. The display device of claim 19, wherein an opening direction of the plurality of light blocking patterns disposed in the second pixel and an opening direction of the plurality of light blocking patterns disposed in the third pixel face each other.
